(19) United States
(12) Patent Application Publication
(10) Pub. No.: US 2010/0104974 A1
(43) Pub. Date: Apr. 29, 2010

(54) POSITIVE RESIST COMPOSITION AND PATTERN FORMING METHOD

(75) Inventors: Yushi Kaneko, Shizuoka (JP); Kunihiko Kodama, Shizuoka (JP); Akinori Shibuya, Shizuoka (JP); Yuko Yoshida, Shizuoka (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/529,927

(22) PCT Filed: Mar. 26, 2008
(86) PCT No.: PCT/JP2008/056534

§ 371 Date: Sep. 4, 2009

(30) Foreign Application Priority Data
Mar. 28, 2007 (JP) 2007-085209
Mar. 19, 2008 (JP) 2008-071481

(51) Int. Cl. G03F 7/20; G03F 7/004

(52) U.S. Cl. 430/270.1; 430/326

(57) ABSTRACT

A positive resist composition comprises: (A) a compound that generates an acid upon irradiation with an actinic ray or radiation; and (B) a resin that has an acid-decomposable repeating unit represented by formula (I′), has a dispersity of 1.5 or less and increases its solubility in an alkali developer by action of an acid,

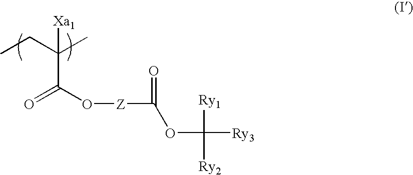

wherein Xa₁ represents a hydrogen atom, an alkyl group, a cyano group or a halogen atom; Ry₁ to Ry₃ each independently represents an alkyl group or a cycloalkyl group, and at least two members out of Ry₁ to Ry₃ may combine to form a ring structure; and Z represents a divalent linking group.

### TECHNICAL FIELD

The present invention relates to a production process of a polymer for use in the process of producing a semiconductor such as IC, in the production of a circuit board of liquid crystal display devices, thermal heads and the like, and in other photofabrication processes; a positive resist composition containing a polymer produced by the production process; a pattern forming method using the composition; and a compound used for the production of the polymer. More specifically, the present invention relates to a production process of a polymer suitably used in the case of employing an exposure light source emitting far ultraviolet light or the like at a wavelength of 250 nm or less, preferably 220 nm or less, or an irradiation source emitting electron beam or the like; a positive resist composition containing a polymer produced by the production process; a pattern forming method using the composition; and a compound used for the production of the polymer.

### BACKGROUND ART

A chemical amplification photosensitive composition is a pattern forming material capable of forming a pattern on a substrate by producing an acid in the exposed area upon irradiation with radiation such as far ultraviolet light and through a reaction using this acid as the catalyst, causing the area irradiated with actinic radiation and the area not irradiated therewith to change the solubility in a developer.

In the case of using a KrF excimer laser as the exposure light source, a resin having small absorption in the region of 248 nm and having a basic skeleton of poly(hydroxystyrene) is predominantly used as the main component, and this is an excellent system capable of forming a good pattern with high sensitivity and high resolution in comparison to the conventional naphthoquinonediazide/novolak resin system.

On the other hand, in the case of using a light source emitting light at a shorter wavelength, for example, in using an ArF excimer laser (193 nm) as the exposure light source, the above-described chemical amplification system is insufficient because the compound having an aromatic group substantially exhibits large absorption in the region of 193 nm.

For this reason, a resist containing a resin having an alicyclic hydrocarbon structure has been developed for use with an ArF excimer laser. Various improvements have been made on the resin for an ArF excimer laser and, for example, as regards the alicyclic acid-decomposable repeating unit, various characteristics have been improved by introducing a repeating unit having a spacer portion between the main chain and an acid-decomposable group (see, JP-A-2005-331918, JP-A-2004-184637 and JP-A-2003-330192).

However, the resin having a spacer part exhibits a high glass transition temperature as compared with the resin not having a spacer part and allows for a very high acid diffusion rate, giving rise to a problem that the exposure latitude (EL) at the formation of a fine pattern with a line width of 100 nm or less is worsened. Even when a resin having introduced thereinto a repeating unit having a spacer portion, it is very difficult to improve particularly the pattern collapse. Improvements are demanded in this respect.

### DISCLOSURE OF THE INVENTION

Accordingly, an object of the present invention is to provide a positive photosensitive composition ensuring that even in the formation of a fine pattern, the pattern collapse and line edge roughness performance are improved and a pattern with good profile is foamed, and a pattern forming method using the composition.

As a result of intensive studies to achieve the above-described object, the present inventors have found that unexpectedly, EL can be improved by a positive resist composition comprising a resin having introduced thereinto a repeating unit having a spacer portion, where the dispersity (weight average molecular weight/number average molecular weight) of the resin is 1.5 or less.

The present invention comprises the following constructions.

<1> A positive resist composition comprising:

(A) a compound that generates an acid upon irradiation with an actinic ray or radiation; and

(B) a resin that has an acid-decomposable repeating unit represented by formula (I′), has a dispersity of 1.5 or less and increases its solubility in an alkali developer by action of an acid,

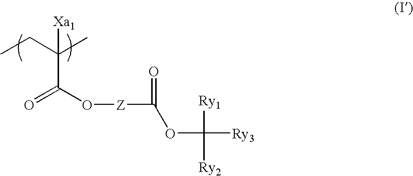

wherein Xa₁ represents a hydrogen atom, an alkyl group, a cyano group or a halogen atom;

Ry₁ to Ry₃ each independently represents an alkyl group or a cycloalkyl group, and at least two members out of Ry₁ to Ry₃ may combine to form a ring structure; and

Z represents a divalent linking group.

<2> The positive resist composition as described in <1>, wherein the resin (B) is a resin produced by living radical polymerization.

<3> The positive resist composition as described in <1> or <2>, wherein the resin (B) is a resin polymerized in the presence of a chain transfer agent represented by formula (CT):

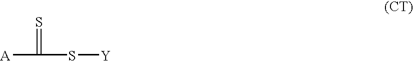

wherein A represents an alkyl group, a cycloalkyl group, an alkoxy group, an alkylthio group, an arylthio group, a heterocyclic thio group, an aryl group or a heterocyclic group; and

Y represents a group capable of releasing a radical.

<4> The positive resist composition as described in any one of <1> to <3>, further comprising a basic compound.

<5> A pattern forming method comprising: forming a film from the positive resist composition described in <1> to <4>; and exposing and developing the film.

### BEST MODE FOR CARRYING OUT THE INVENTION

The best mode for carrying out the present invention is described below.

Incidentally, in the context of the present invention, when a group (atomic group) is denoted without specifying whether substituted or unsubstituted, the group includes both a group having no substituent and a group having a substituent. For example, an “alkyl group” includes not only an alkyl group having no substituent (unsubstituted alkyl group) but also an alkyl group having a substituent (substituted alkyl group). Also, the term “carbon number of a certain functional group” indicates the total carbon number of the functional group excluding the carbon number of the substituent.

(A) Compound Capable of Generating an Acid Upon Irradiation with an Actinic Ray or Radiation

The photosensitive composition of the present invention contains (A) a compound capable of generating an acid upon irradiation with an actinic ray or radiation (hereinafter sometimes referred to as an “acid generator” or a “photoacid generator”).

The photo acid generator which can be used may be appropriately selected from a photoinitiator for photocationic polymerization, a photoinitiator for photoradical polymerization, a photo-decoloring agent for coloring matters, a photo-discoloring agent, a compound known to generate an acid upon irradiation with an actinic ray or radiation and used for microresist or the like, and a mixture thereof.

Examples thereof include a diazonium salt, a phosphonium salt, a sulfonium salt, an iodonium salt, an imidosulfonate, an oxime sulfonate, a diazodisulfone, a disulfone and an o-nitrobenzyl sulfonate.

Also, a compound where such a group or compound capable of generating an acid upon irradiation with an actinic ray or radiation is introduced into the main or side chain of the polymer, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853 and JP-A-63-146029, may be used.

Furthermore, compounds capable of generating an acid by the effect of light described, for example, in U.S. Pat. No. 3,779,778 and European Patent 126,712 may also be used.

Out of the compounds capable of decomposing upon irradiation with an actinic ray or radiation to generate an acid, which can be used in combination, the compounds represented by the following formulae (ZI), (ZII) and (ZIII) are preferred.

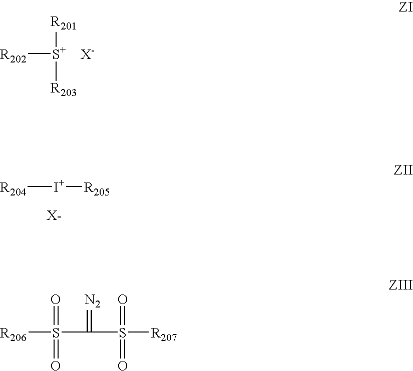

In formula (ZI), R₂₀₁, R₂₀₂ and R₂₀₃ each independently represents an organic group.

X⁻ represents a non-nucleophilic anion, and preferred examples thereof include sulfonate anion, carboxylate anion, bis(alkylsulfonyl)amide anion, tris(alkylsulfonyl)methide anion, BF₄⁻, PF₆⁻ and SbF₆⁻. The anion is preferably an organic anion containing a carbon atom.

The preferred organic anion includes organic anions represented by the following formulae AN1 to AN4:

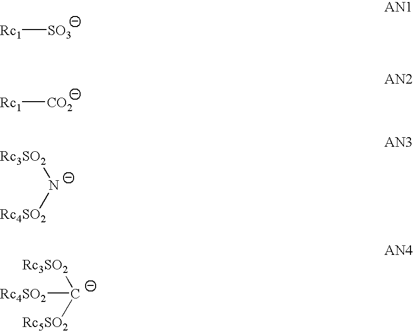

In formulae AN1 to AN4, Rc₁ represents an organic group.

Rd₁ represents a hydrogen atom or an alkyl group.

The organic group in Rc₁ includes an organic group preferably having a carbon number of 1 to 30 and is preferably an alkyl, an aryl group, or a group where a plurality of such groups are connected through a single bond or a linking group such as —O—, —CO₂—, —S—, —SO₃— and —SO₂N(Rd₁)-.

Rd₁ represents a hydrogen atom or an alkyl group and may form a ring structure together with the alkyl or aryl group to which Rd₁ is bonded.

The organic group of Rc₁ is more preferably an alkyl group substituted by a fluorine atom or a fluoroalkyl group at the 1-position, or a phenyl group substituted by a fluorine atom or a fluoroalkyl group.

By virtue of having a fluorine atom or a fluoroalkyl group, the acidity of the acid generated upon irradiation with light increases and the sensitivity is enhanced.

When Rc₁ has 5 or more carbon atoms, at least one carbon atom is preferably substituted by a hydrogen atom, and it is more preferred that the number of hydrogen atoms is larger than the number of fluorine atoms. The absence of a perfluoroalkyl group having a carbon number of 5 or more enables reduction in the toxicity to ecology.

The most preferred embodiment of Rc₁ is a group represented by the following formula:

Rc₇-Ax-Rc₆-

Rc₆ represents a perfluoroalkylene group having a carbon number of 4 or less, preferably from 2 to 4, more preferably 2 or 3, or a phenylene group substituted by from 3 to 5 fluorine atoms and/or from 1 to 3 fluoroalkyl groups.

Ax represents a linking group (preferably a single bond, —O—, —CO₂—, —S—, —SO₃— or —SO₂N(Rd₁)-). Rd₁ represents a hydrogen atom or an alkyl group and may combine with Rc₇ to form a ring structure.

Rc₇ represents a hydrogen atom, a fluorine atom, an alkyl group (linear or branched), a cycloalkyl group (monocyclic or polycyclic), or an aryl group. The alkyl group, cycloalkyl group and aryl group each preferably contains no fluorine atom as the substituent.

Rc₃, Rc₄ and Rc₅ each independently represents an organic group. The preferred organic groups in Rc₃, Rc₄ and Rc₅ are the same as the preferred organic groups in Rc₁.

Rc₃ and Rc₄ may combine to form a ring.

The group formed by combining Rc₃ and Rc₄ includes an alkylene group and an arylene group and is preferably a perfluoroalkylene group having a carbon number of 2 to 4. When Rc₃ and Rc₄ combine to form a ring, the acidity of the acid generated upon irradiation with light increases and this is preferred because the sensitivity is enhanced.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group.

Examples of the group formed by combining two members out of R₂₀₁ to R₂₀₃ include an alkylene group (e.g., butylene, pentylene).

Specific examples of the organic group as R₂₀₁, R₂₀₂ and R₂₀₃ include corresponding groups in the compounds (ZI-1), (ZI-2) and (ZI-3) which are described later.

The compound may be a compound having a plurality of structures represented by formula (ZI). For example, the compound may be a compound having a structure where at least one of R₂₀₁ to R₂₀₃ in the compound represented by formula (ZI) is bonded to at least one of R₂₀₁ to R₂₀₃ in another compound represented by formula (ZI).

The component (ZI) is more preferably a compound (ZI-1), (ZI-2) or (ZI-3) described below.

The compound (ZI-1) is an arylsulfonium compound where at least one of R₂₀₁ to R₂₀₃ in formula (Z1) is an aryl group, that is, a compound having an arylsulfonium as the cation.

In the arylsulfonium compound, R₂₀₁ to R₂₀₃ all may be an aryl group or a part of R₂₀₁ to R₂₀₃ may be an aryl group with the remaining being an alkyl group.

Examples of the arylsulfonium compound include a triarylsulfonium compound, a diarylalkylsulfonium compound, and an aryldialkylsulfonium compound.

The aryl group in the arylsulfonium compound is preferably an aryl group such as phenyl group and naphthyl group, or a heteroaryl group such as indole residue and pyrrole residue, more preferably a phenyl group or an indole residue. In the case where the arylsulfonium compound has two or more aryl groups, these two or more aryl groups may be the same or different.

The alkyl group which is present, if desired, in the arylsulfonium compound is preferably a linear, branched or cyclic alkyl group having a carbon number of 1 to 15, and examples thereof include a methyl group, an ethyl group, a propyl group, an n-butyl group, a sec-butyl group, a tert-butyl group, a cyclopropyl group, a cyclobutyl group, and a cyclohexyl group.

The aryl group and alkyl group of R₂₀₁ to R₂₀₃ each may have, as the substituent, an alkyl group (for example, an alkyl group having a carbon number of 1 to 15), an aryl group (for example, an aryl group having a carbon number of 6 to 14), an alkoxy group (for example, an alkoxy group having a carbon number of 1 to 15), a halogen atom, a hydroxyl group or a phenylthio group. The substituent is preferably a linear, branched or cyclic alkyl group having a carbon number of 1 to 12, or a linear, branched or cyclic alkoxy group having a carbon number of 1 to 12, and most preferably an alkyl group having a carbon number of 1 to 4, or an alkoxy group having a carbon number of 1 to 4. The substituent may be substituted to any one of three members R₂₀₁ to 8₂₀₃ or may be substituted to all of these three members. In the case where R₂₀₁ to R₂₀₃ are an aryl group, the substituent is preferably substituted at the p-position of the aryl group.

The compound (ZI-2) is described below.

The compound (ZI-2) is a compound where R₂₀₁ to R₂₀₃ in formula (ZI) each independently represents an aromatic ring-free organic group. The aromatic ring as used herein includes an aromatic ring containing a heteroatom.

The aromatic ring-free organic group as R₂₀₁ to R₂₀₃ generally has a carbon number of 1 to 30, preferably from 1 to 20.

R₂₀₁ to R₂₀₃ each is independently preferably an alkyl group, a 2-oxoalkyl group, an alkoxycarbonylmethyl group, an allyl group or a vinyl group, more preferably a linear, branched or cyclic 2-oxoalkyl group or an alkoxycarbonylmethyl group, and most preferably a linear or branched 2-oxoalkyl group.

The alkyl group as R₂₀₁ to R₂₀₃ may be linear, branched or cyclic and is preferably a linear or branched alkyl group having a carbon number of 1 to 10 (e.g., methyl, ethyl, propyl, butyl, pentyl) or a cyclic alkyl group having a carbon number of 3 to 10 (e.g., cyclopentyl, cyclohexyl, norbornyl).

The 2-oxoalkyl group as R₂₀₁ to R₂₀₃ may be linear, branched or cyclic and is preferably a group having >C═O at the 2-position of the above-described alkyl group.

The alkoxy group in the alkoxycarbonylmethyl group as R₂₀₁ to R₂₀₃ is preferably an alkoxy group having a carbon number of 1 to 5 (e.g., methoxy, ethoxy, propoxy, butoxy, pentoxy).

R₂₀₁ to R₂₀₃ each may be further substituted by a halogen atom, an alkoxy group (for example, an alkoxy group having a carbon number of 1 to 5), a hydroxyl group, a cyano group or a nitro group.

Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., butylene, pentylene).

The compound (ZI-3) is a compound represented by the following formula (ZI-3), and this is a compound having a phenacylsulfonium salt structure.

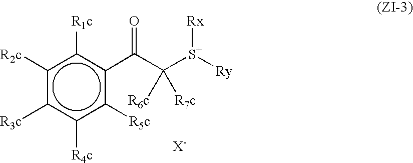

R_{1c} to R_{5c} each independently represents a hydrogen atom, an alkyl group, an alkoxy group or a halogen atom.

R_{6c} and R_{7c} each represents a hydrogen atom or an alkyl group.

Rₓ and R_{y} each independently represents an alkyl group, a 2-oxoalkyl group, an alkoxycarbonylmethyl group, an allyl group or a vinyl group.

Any two or more members out of R_{1c} to R_{5c} or a pair of Rₓ and R_{y} may combine with each other to form a ring structure, and the ring structure may contain an oxygen atom, a sulfur atom, an ester bond or an amide bond.

The alkyl group as R_{lc} to R_{5c} may be linear, branched or cyclic and is, for example, an alkyl group having a carbon number of 1 to 20, preferably a linear or branched alkyl group having a carbon number of 1 to 12 (for example, a methyl group, an ethyl group, a linear or branched propyl group, a linear or branched butyl group, or a linear or branched pentyl group), or a cyclic alkyl group having a carbon number of 3 to 8 (e.g., cyclopentyl, cyclohexyl).

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (for example, a methoxy group, an ethoxy group, a linear or branched propoxy group, a linear or branched butoxy group, or a linear or branched pentoxy group), or a cyclic alkoxy group having a carbon number of 3 to 8 (e.g., cyclopentyloxy, cyclohexyloxy).

A compound where any one of R_{1c} to R_{5c} is a linear, branched or cyclic alkyl group or a linear, branched or cyclic alkoxy group is preferred, and a compound where the sum of carbon numbers of R_{1c} to R_{5c} is from 2 to 15 is more preferred. By virtue of this construction, the solvent solubility is more enhanced and generation of particles during storage is suppressed.

The alkyl group as Rₓ and R_{y} is the same as the alkyl group of R_{1c} to R_{5c}.

The 2-oxoalkyl group includes a group having >C═O at the 2-position of the alkyl group as R_{1c} to R_{5c}.

The alkoxy group in the alkoxycarbonylmethyl group is the same as the alkoxy group of R_{1c} to R_{5c}.

Examples of the group formed by combining Rₓ and R_{y} include a butylene group and a pentylene group.

Rₓ and R_{y} each is preferably an alkyl group having a carbon number of 4 or more, more preferably 6 or more, still more preferably 8 or more.

In formulae (ZII) and (ZIII), R₂₀₄ to R₂₀₇ each independently represents an aryl group which may have a substituent, or an alkyl group which may have a substituent.

The aryl group of R₂₀₄ to R₂₀₇ is preferably a phenyl group or a naphthyl group, more preferably a phenyl group.

The alkyl group of R₂₀₄ to R₂₀₇ may be linear, branched or cyclic and is preferably a linear or branched alkyl group having a carbon number of 1 to 10 (e.g., methyl, ethyl, propyl, butyl, pentyl), or a cyclic alkyl group having a carbon number of 3 to 10 (e.g., cyclopentyl, cyclohexyl, norbornyl).

Examples of the substituent which R₂₀₄ to R₂₀₇ each may have include an alkyl group (for example, an alkyl group having a carbon number of 1 to 15), an aryl group (for example, an aryl group having a carbon number of 6 to 15), an alkoxy group (for example, an alkoxy group having a carbon number of 1 to 15), a halogen atom, a hydroxyl group, and a phenylthio group.

X⁻ represents a non-nucleophilic anion and is the same as the non-nucleophilic anion of X⁻ in formula (I).

Out of the compounds capable of decomposing upon irradiation with an actinic ray or radiation to generate an acid, preferred compounds further include the compounds represented by the following formulae (ZIV), (ZV) and (ZVI):

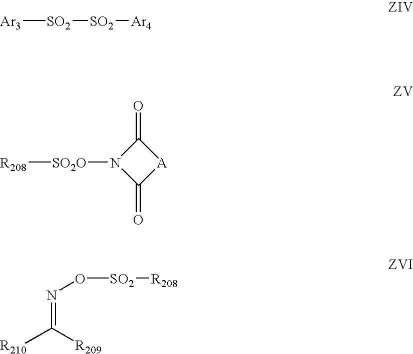

In formulae (ZIV) to (ZVI), Ar₃ and Ar₄ each independently represents a substituted or unsubstituted aryl group.

R₂₀₈ represents a substituted or unsubstituted alkyl group or a substituted or unsubstituted aryl group.

R₂₀₉ and R₂₁₀ each represents a substituted or unsubstituted alkyl group, a substituted or unsubstituted aryl group, or an electron-withdrawing group. R₂₀₉ is preferably a substituted or unsubstituted aryl group.

R₂₁₀ is preferably an electron-withdrawing group, more preferably a cyano group or a fluoroalkyl group.

A represents a substituted or unsubstituted alkylene group, a substituted or unsubstituted alkenylene group, or a substituted or unsubstituted arylene group.

Among the compounds capable of decomposing upon irradiation with an actinic ray or radiation to generate an acid, the compounds represented by formulae (ZI) to (ZIII) are preferred, the compound represented by formula (ZI) is more preferred, and the compounds represented by formulae (ZI-1) to (ZI-3) are most preferred.

Furthermore, a compound capable of generating an acid corresponding to formula AN1, AN3 or AN4, that is, an acid represented by the following formula AC1, AC3 or AC4, upon irradiation with an actinic ray or radiation is preferred. In the formulae, each substituent has the same meaning as that in formulae AN1, AN3 and AN4.

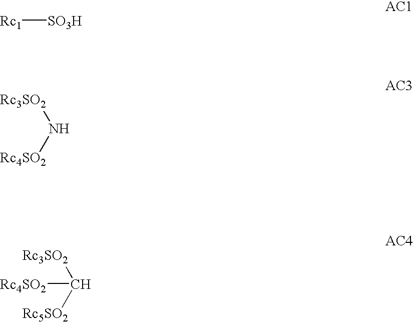

That is, a most preferred embodiment of the component (A) is a compound where in the structure of formula (ZI), X⁻ is an anion selected from formulae AN1, AN3 and AN4.

Out of the compounds capable of decomposing upon irradiation with an actinic ray or radiation to generate an acid, particularly preferred examples are set forth below.

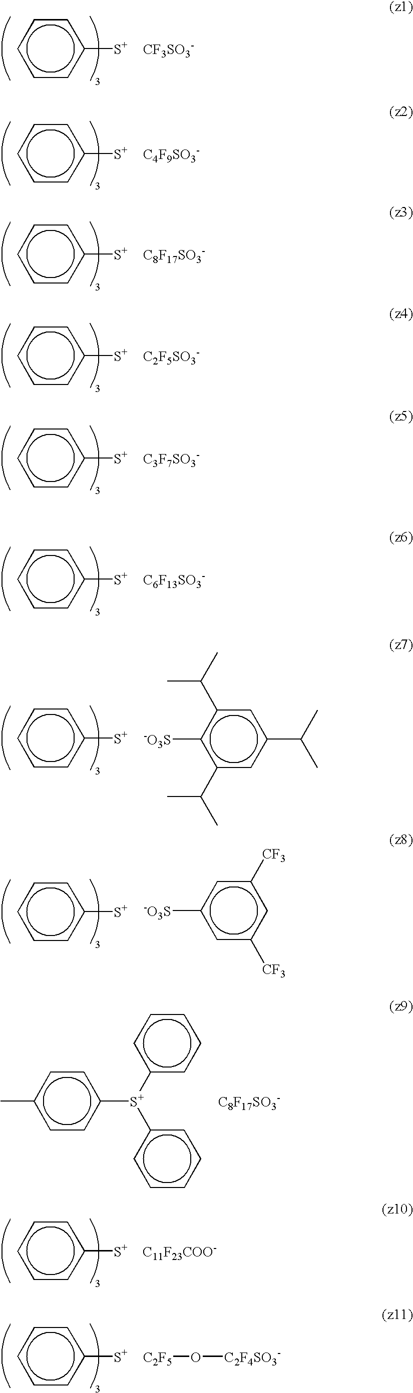

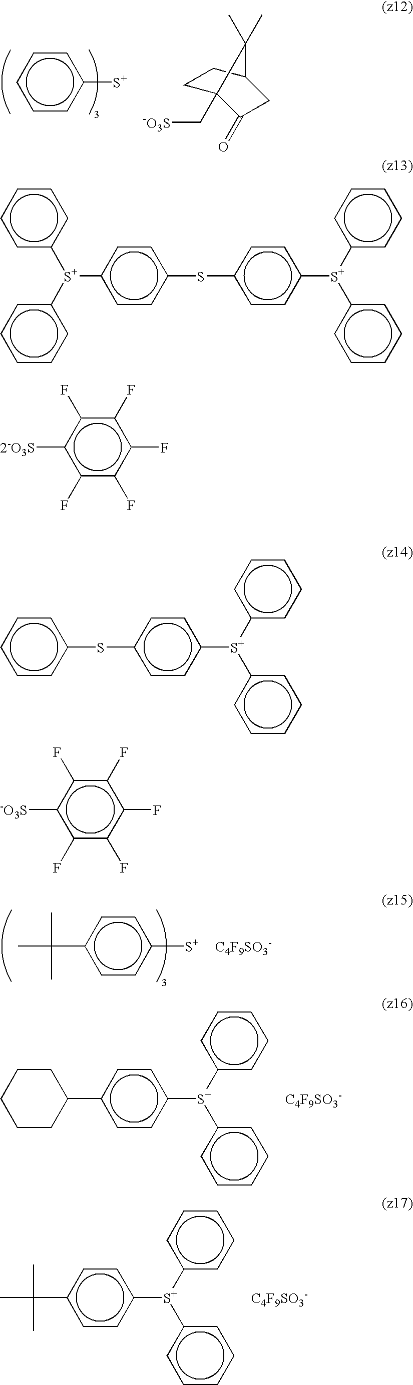

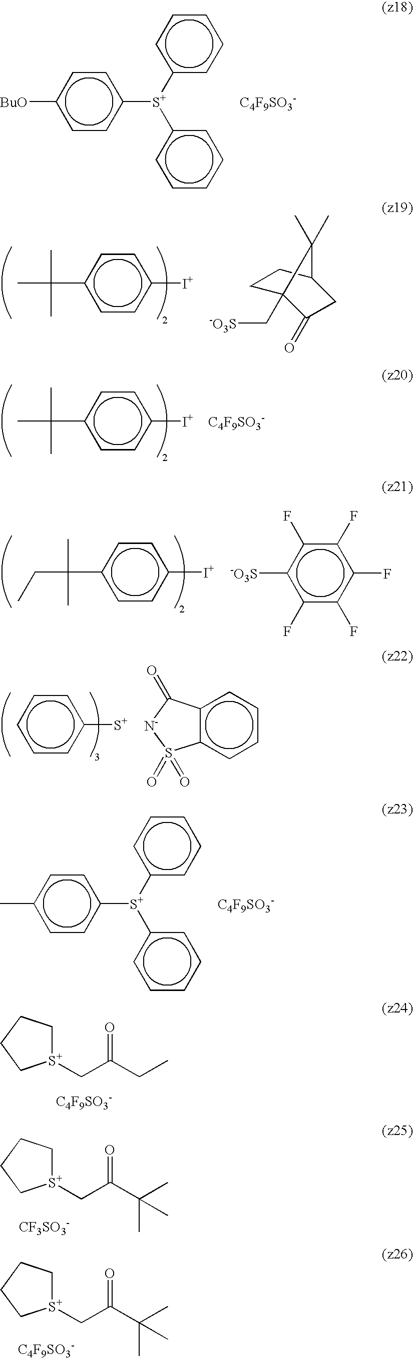

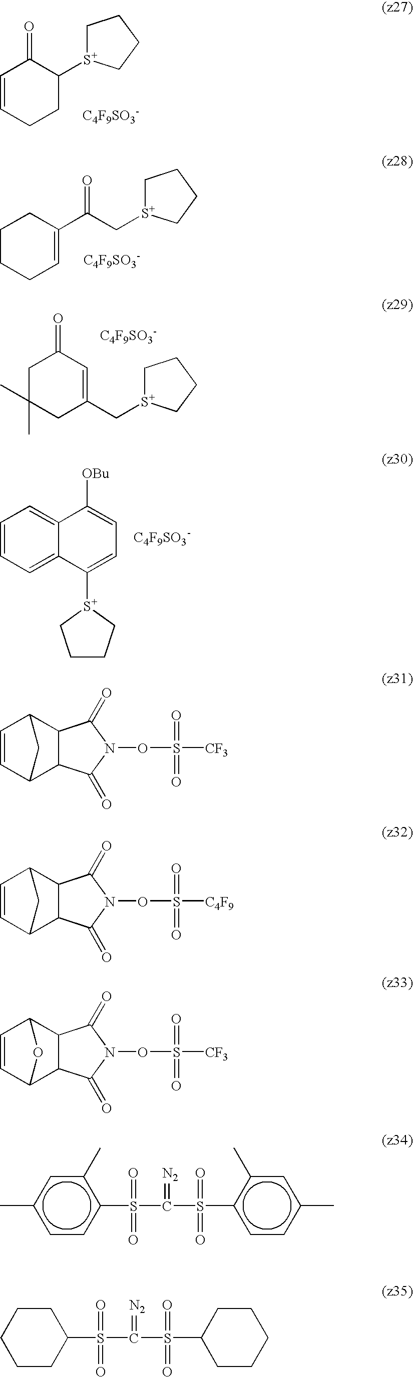

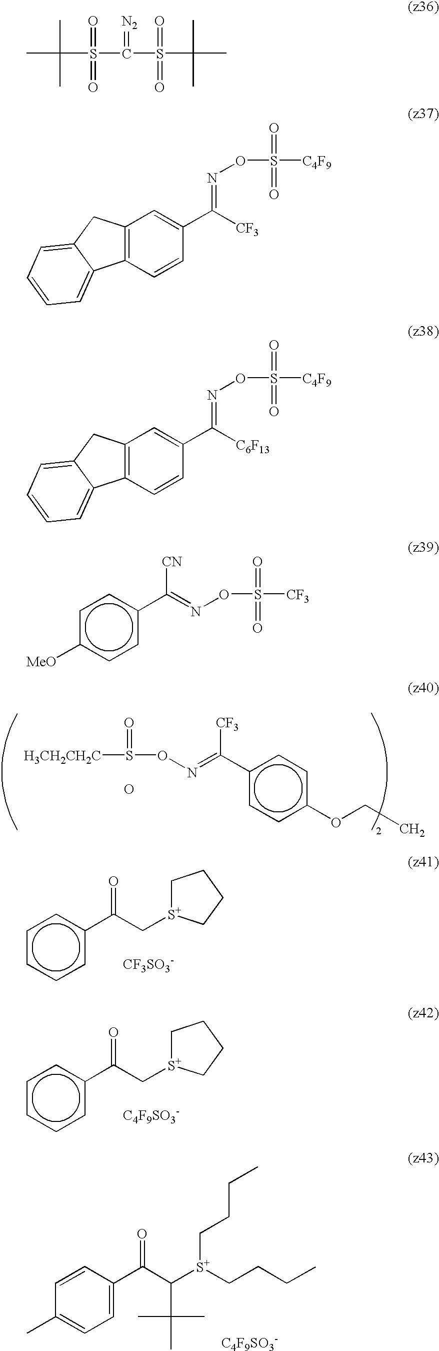

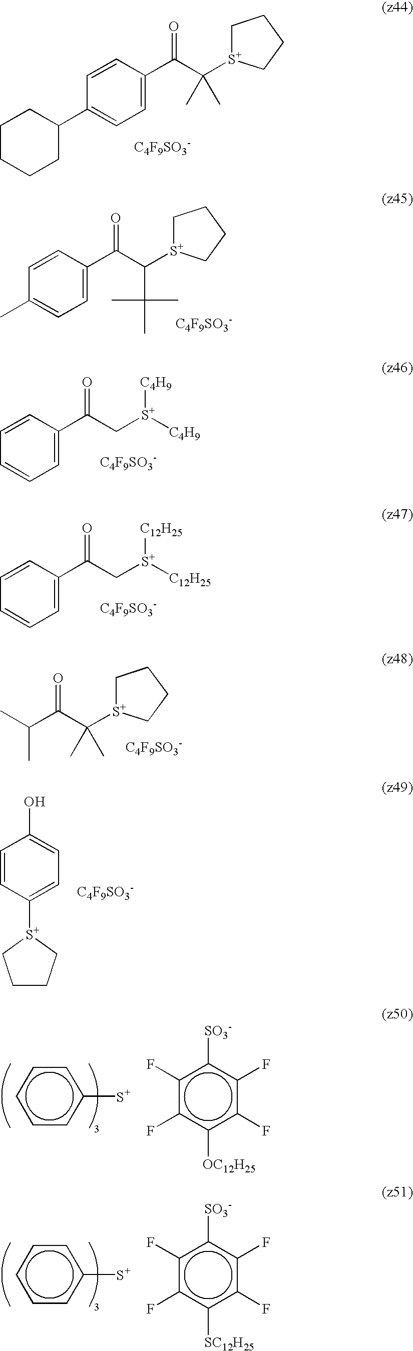

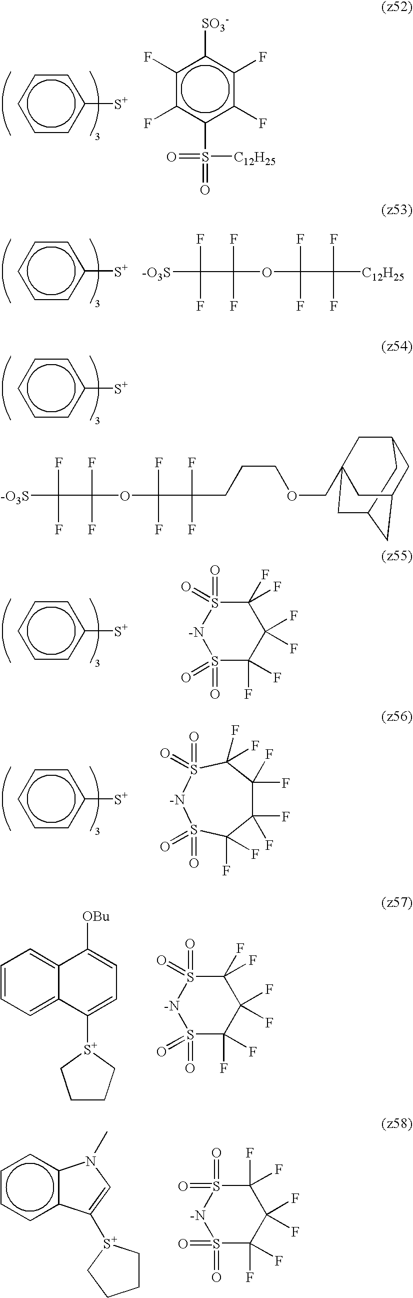

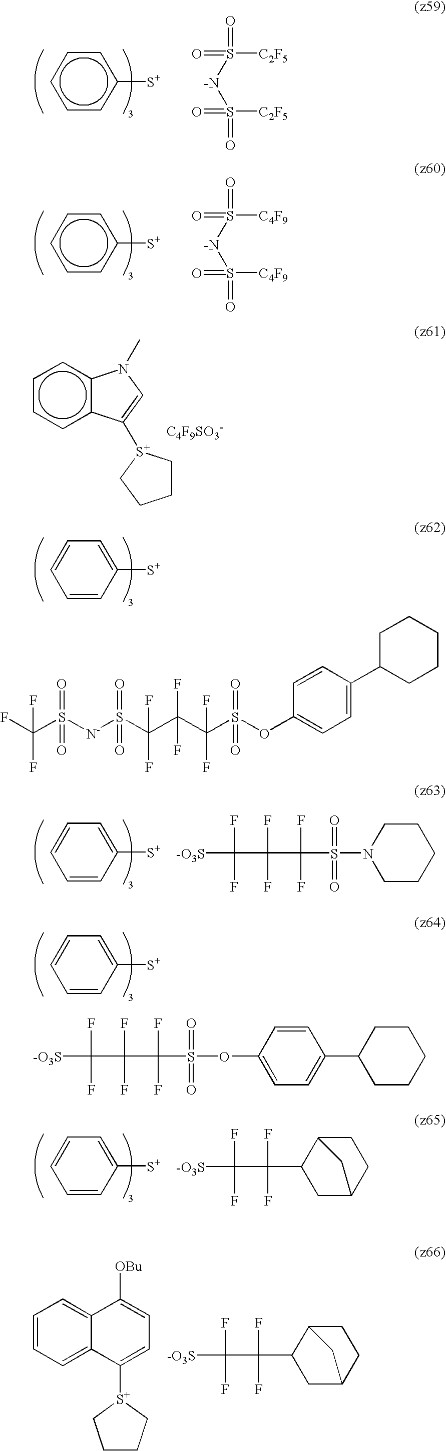

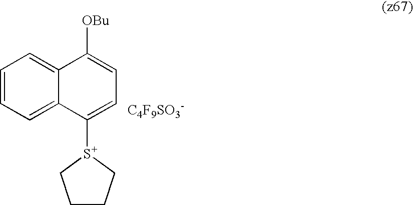

One of these acid generators may be used alone, or two or more kinds thereof may be used in combination. In the case of using two or more kinds in combination, compounds capable of generating two kinds of organic acids differing in the total number of atoms except for hydrogen atom by 2 or more are preferably combined.

The content of the acid generator in the composition is preferably from 0.1 to 20 mass %, more preferably from 0.5 to 10 mass %, still more preferably from 1 to 7 mass %, based on the entire solid content of the resist composition.

(B) Resin that Increases its Solubility in an Alkali Developer Increases by Action of an Acid

The resin that increases its solubility in an alkali developer increases by action of an acid, which is used in the positive photosensitive composition of the present invention, is a resin having an acid-decomposable repeating unit represented by the following formula (I′) and having a dispersity of 1.5 or less (hereinafter sometimes referred to as a “resin as the component (B)” or a “resin (B)”).

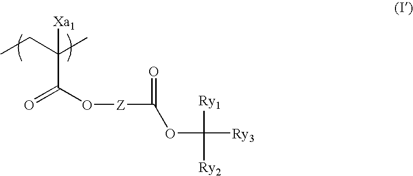

In formula (I′), Xa₁ represents a hydrogen atom, an alkyl group, a cyano group or a halogen atom.

Ry₁ to Ry₃ each independently represents an alkyl group or a cycloalkyl group, and at least two members out of Ry₁ to Ry₃ may combine to form a monocyclic or polycyclic hydrocarbon ring structure.

Z represents a divalent linking group.

In formula (I′), the alkyl group of Xa₁ may be substituted by a hydroxyl group, a halogen atom or the like.

Xa₁ is preferably a hydrogen atom or a methyl group.

The alkyl group of Ry₁ to Ry₃ may be either a linear alkyl group or a branched alkyl group and may have a substituent. The linear or branched alkyl group preferably has a carbon number of 1 to 8, more preferably from 1 to 4, and examples thereof include a methyl group, an ethyl group, a propyl group, an isopropyl group, a butyl group, an isobutyl group, and a tert-butyl group, with a methyl group and an ethyl group being preferred.

The cycloalkyl group of Ry₁ to Ry₃ includes, for example, a monocyclic cycloalkyl group having a carbon number of 3 to 8, and a polycyclic cycloalkyl group having a carbon number of 7 to 14, and may have a substituent. Preferred examples of the monocyclic cycloalkyl group include a cyclopentyl group, a cyclohexyl group and a cyclopropyl group, and preferred examples of the polycyclic cycloalkyl group include an adamantyl group, a norbornane group, a tetracyclododecanyl group, a tricyclodecanyl group an a diadamantyl group.

The monocyclic hydrocarbon ring structure formed by combining at least two members out of Ry₁ to Ry₃ is preferably a cyclopentyl group or a cyclohexyl group. The polycyclic hydrocarbon ring structure formed by combining at least two members out of Ry₁ to Ry₃ is preferably an adamantyl group, a norbornyl group or a tetracyclododecanyl group.

Z is preferably a divalent linking group having a carbon number of 1 to 20, more preferably an alkylene group having a carbon number of 1 to 4, a cyclic alkylene group having a carbon number of 5 to 20, or a combination thereof.

The chain alkylene group having a carbon number of 1 to 4 includes a methylene group, an ethylene group, a propylene group and a butylene group and may be linear or branched. The chain alkylene group is preferably a methylene group.

The cyclic alkylene group having a carbon number of 5 to 20 includes a monocyclic cycloalkylene group such as cyclopentylene group and cyclohexylene group, and a polycyclic cycloalkylene group such as norbornylene group and adamantylene group. The cyclic alkylene group is preferably an adamantylene group.

The polymerizable compound for forming the repeating unit represented by formula (I′) can be easily synthesized by a known method. For example, using the same means as the method described in JP-A-2005-331918, an alcohol and a carboxylic acid halogenide compound are reacted under basic conditions as shown in the following scheme, and the reaction product is reacted with a carboxylic acid compound under basic conditions, whereby the polymerizable compound can be synthesized.

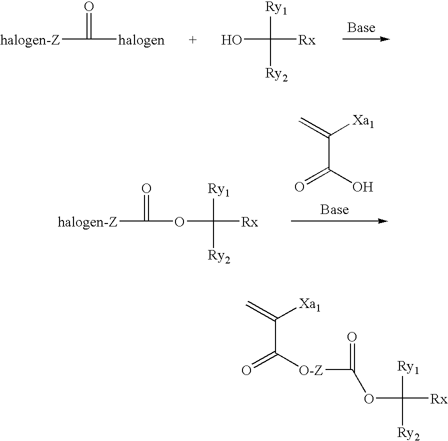

Specific preferred examples of the repeating unit represented by formula (I′) are set forth below, but the present invention is not limited thereto. Incidentally, Xa₁ is the same meaning as Xa₁ in formula in formula (I′).

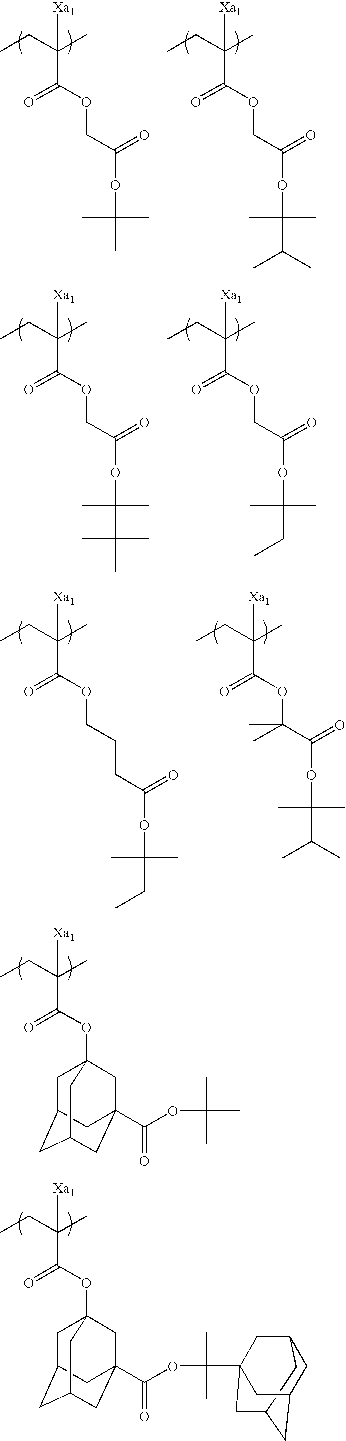

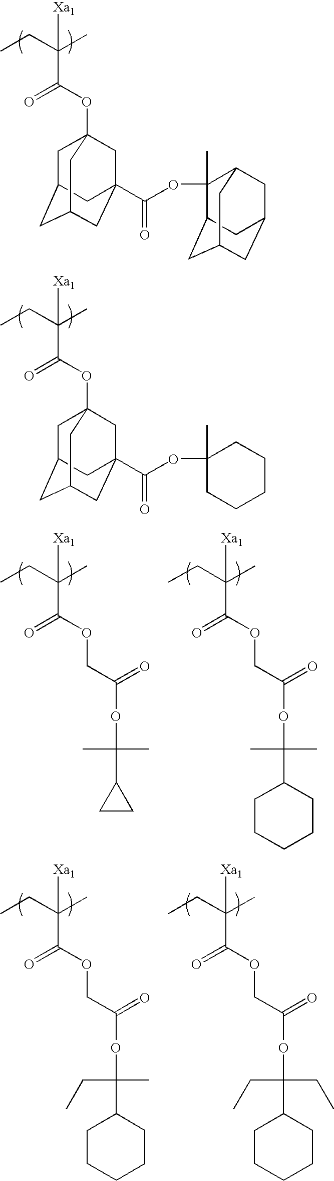

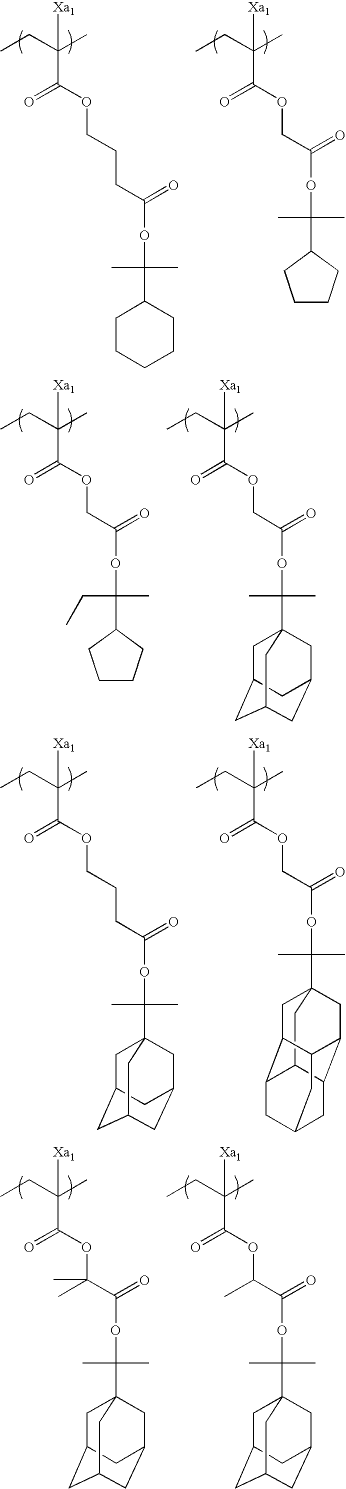

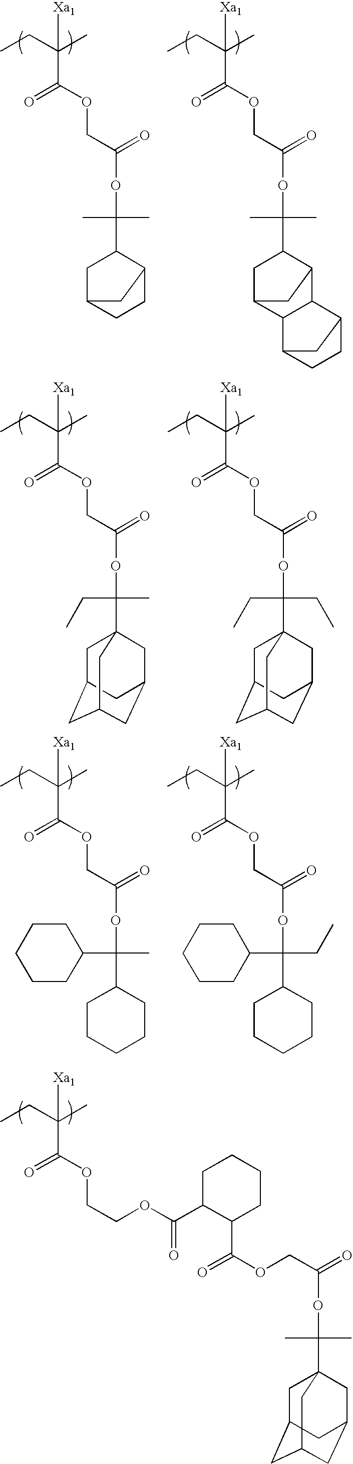

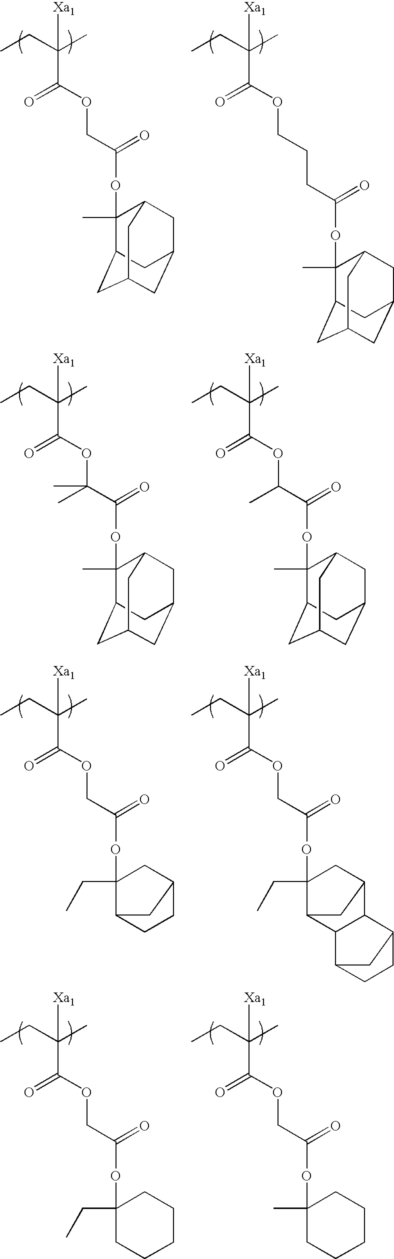

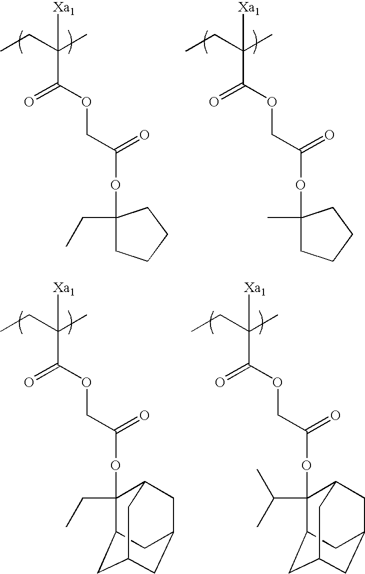

The content of the repeating unit represented by formula (I′) is preferably from 10 to 60 mol %, and most preferably from 20 to 50 mol %.

The repeating unit represented by formula (I′) decomposes under the action of an acid to produce a carboxyl group, as a result, its solubility in an alkali developer increases.

In particular, it is preferred that at least one of Ry₁, Ry₂ and Ry₃ in formula (I′) is a cycloalkyl ring or two members selected from Ry₁, Ry₂ and Ry₃ are linked to form a ring, and it is most preferred that Ry₁ is cyclopentyl or cyclohexyl and Ry₂ and Ry₃ each is an alkyl group having a carbon number of 1 to 5, or Ry₁ and Ry₂ are linked to form a cyclopentyl ring or a cyclohexyl ring and Ry₃ is an alkyl group having a carbon number of 1 to 5.

The alkyl group, cycloalkyl group, alkoxy group, alkylthio group, arylthio group, heterocyclic thio group, aryl group and heterocyclic group in formula (I′) and formula (CT) described later each may have a substituent.

Examples of the substituent which the alkyl group, cycloalkyl group, alkoxy group, alkylthio group, arylthio group, heterocyclic thio group, aryl group and heterocyclic group in formula (I′) and formula (CT) described later each may have include a halogen atom, an alkyl group, a cycloalkyl group, an alkenyl group, a cycloalkenyl group, an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an amino group (including an alkylamino group and an anilino group), an acylamino group, an aminocarbonylamino group, an alkoxycarbonylamino group, an aryloxycarbonylamino group, a sulfamoylamino group, an alkyl- or aryl-sulfonylamino group, a mercapto group, an alkylthio group, an arylthio group, a heterocyclic thio group, a sulfamoyl group, a sulfino group, a sulfa group, an alkyl- or aryl-sulfino group, an alkyl- or aryl-sulfonyl group, an acyl group, an aryloxycarbonyl group, an alkoxycarbonyl group, a carbamoyl group, an aryl or heterocyclic azo group, an imido group, a phosphino group, a phosphinyl group, a phosphinyloxy group, a phosphinylamino group and a silyl group.

These substituents each is described in more detail below.

The halogen atom includes a fluorine atom, a chlorine atom, a bromine atom and an iodine atom.

The alkyl group is, for example, a linear or branched, substituted or unsubstituted alkyl group and is preferably an alkyl group having a carbon number of 1 to 30, more preferably from 1 to 10, and examples thereof include methyl, ethyl, n-propyl group, isopropyl group, tert-butyl, n-octyl, 2-chloroethyl, 2-cyanoethyl and 2-ethylhexyl.

The cycloalkyl group is preferably a substituted or unsubstituted cycloalkyl group having a carbon number of 3 to 30, more preferably from 3 to 10, such as cyclohexyl and cyclopentyl, or a polycycloalkyl group, for example, a group having a polycyclic structure, such as bicycloalkyl group (a substituted or unsubstituted bicycloalkyl group preferably having a carbon number of 5 to 30, more preferably from 5 to 15, e.g., bicyclo[1,2,2]heptan-2-yl, bicyclo[2,2,2]octan-3-yl) and tricycloalkyl group. A monocyclic cycloalkyl group and a bicycloalkyl group are more preferred, and a monocyclic cycloalkyl group is still more preferred. The cycloalkyl group is preferably a 3- to 10-membered ring.

The alkenyl group is a linear or branched, substituted or unsubstituted alkenyl group and is preferably an alkenyl having a carbon number of 2 to 30, more preferably from 2 to 10, and examples thereof include vinyl, allyl, prenyl, geranyl and oleyl.

The cycloalkenyl group is preferably a substituted or unsubstituted cycloalkenyl group having a carbon number of 3 to 30, more preferably from 3 to 10, such as 2-cyclopenten-1-yl and 2-cyclohexen-1-yl, or a polycycloalkenyl group such as bicycloalkenyl group (a substituted or unsubstituted bicycloalkenyl group preferably having a carbon number of 5 to 30, more preferably from 5 to 15, e.g., bicyclo[2,2,1]hept-2-en-1-yl, bicyclo[2,2,2]oct-2-en-4-yl)), tricycloalkenyl group and bicycloalkenyl group. A monocyclic cycloalkenyl group is more preferred.

The alkynyl group is preferably a substituted or unsubstituted alkynyl group having a carbon number of 2 to 30, more preferably from 2 to 15, such as ethynyl, propargyl and trimethylsilylethynyl.

The aryl group is preferably a substituted or unsubstituted aryl group having a carbon number of 6 to 30, more preferably from 6 to 12, and examples thereof include phenyl, p-tolyl, naphthyl, m-chlorophenyl and o-hexadecanoylaminophenyl.

The heterocyclic group is preferably a 5- to 7-membered substituted or unsubstituted, saturated or unsaturated, aromatic or non-aromatic, monocyclic or condensed heterocyclic group, more preferably a heterocyclic group having at least one heteroatom of a nitrogen atom, an oxygen atom or a sulfur atom, with the ring-constituting atom being selected from a carbon atom, a nitrogen atom and a sulfur atom, still more preferably a 5- or 6-membered aromatic heterocyclic group having a carbon number of 3 to 30, yet still more preferably from 5 to 12, and examples thereof include 2-furyl, 2-thienyl, 2-pyridyl, 4-pyridyl, 2-pyrimidinyl and 2-benzothiazolyl.

The alkoxy group is preferably a substituted or unsubstituted alkoxy group having a carbon number of 1 to 30, more preferably from 1 to 10, and examples thereof include methoxy, ethoxy, isopropoxy, tert-butoxy, n-octyloxy and 2-methoxyethoxy.

The aryloxy group is preferably a substituted or unsubstituted aryloxy group having a carbon number of 6 to 30, more preferably from 6 to 12, and examples thereof include phenoxy, 2-methylphenoxy, 2,4-di-tert-amylphenoxy, 4-tert-butylphenoxy, 3-nitrophenoxy and 2-tetradecanoylaminophenoxy.

The silyloxy group is preferably a silyloxy group having a carbon number of 3 to 20, more preferably from 3 to 10, and examples thereof include trimethylsilyloxy and tert-butyldimethylsilyloxy.

The heterocyclic oxy group is preferably a substituted or unsubstituted heterocyclic oxy group having a carbon number of 2 to 30, more preferably from 5 to 12, and the heterocyclic moiety is preferably the heterocyclic moiety described above for the heterocyclic group. Examples of the heterocyclic oxy group include 1-phenyl-tetrazol-5-oxy and 2-tetrahyropyranyloxy.

The acyloxy group is preferably a formyloxy group, a substituted or unsubstituted alkylcarbonyl group having a carbon number of 2 to 30, more preferably from 2 to 10, or a substituted or unsubstituted arylcarbonyloxy group having a carbon number of 6 to 30, more preferably from 6 to 12, and examples thereof include formyloxy, acetyloxy, pivaloyloxy, stearoyloxy, benzoyloxy and p-methoxyphenylcarbonyloxy.

The carbamoyloxy group is preferably a substituted or unsubstituted carbamoyloxy group having a carbon number of 1 to 30, more preferably from 1 to 10, and examples thereof include N,N-dimethylcarbamoyloxy, N,N-diethylcarbamoyloxy, morpholinocarbonyloxy, N,N-di-n-octylaminocarbonyloxy and N-n-octylcarbamoyloxy.

The alkoxycarbonyloxy group is preferably a substituted or unsubstituted alkoxycarbonyloxy group having a carbon number of 2 to 30, more preferably from 2 to 10, and examples thereof include methoxycarbonyloxy, ethoxycarbonyloxy, tert-butoxycarbonyloxy and n-octylcarbonyloxy.

The aryloxycarbonyloxy group is preferably a substituted or unsubstituted aryloxycarbonyloxy group having a carbon number of 7 to 30, more preferably from 7 to 15, and examples thereof include phenoxycarbonyloxy, p-methoxyphenoxycarbonyloxy and p-n-hexadecyloxyphenoxycarbonyloxy.

The amino group is preferably an amino group, a substituted or unsubstituted alkylamino group having a carbon number of 1 to 30, more preferably from 1 to 10, a substituted or unsubstituted arylamino group having a carbon number of 6 to 30, more preferably from 6 to 12, or a heterocyclic amino group having a carbon number of 0 to 30, and examples thereof include amino, methylamino, dimethylamino, anilino, N-methylanilino, diphenylamino and N-1,3,5-triazin-2-ylamino.

The acylamino group is preferably an formylamino group, a substituted or unsubstituted alkylcarbonylamino group having a carbon number of 1 to 30, more preferably from 1 to 10, or a substituted or unsubstituted arylcarbonylamino group having a carbon number of 6 to 30, more preferably from 6 to 12, and examples thereof include formylamino, acetylamino, pivaloyl amino, lauroylamino, benzoylamino and 3,4,5-tri-n-octyloxyphenylcarbonylamino.

The aminocarbonylamino group is preferably a substituted or unsubstituted aminocarbonylamino group having a carbon number of 1 to 30, more preferably from 1 to 10, and examples thereof include carbamoylamino, N,N-dimethylaminocarbonylamino, N,N-diethylaminocarbonylamino and morpholinocarbonylamino.

The alkoxycarbonylamino group is preferably a substituted or unsubstituted alkoxycarbonylamino group having a carbon number 2 to 30, more preferably from 2 to 10, and examples thereof include methoxycarbonylamino, ethoxycarbonylamino, tert-butoxycarbonylamino, n-octadecyloxycarbonylamino and N-methyl-methoxycarbonylamino.

The aryloxycarbonylamino group is preferably a substituted or unsubstituted aryloxycarbonylamino group having a carbon number of 7 to 30, more preferably from 7 to 10, and examples thereof include phenoxycarbonylamino, p-chlorophenoxycarbonylamino and m-n-octyloxyphenoxycarbonylamino.

The sulfamoylamino group is preferably a substituted or unsubstituted sulfamoylamino group having a carbon number of 0 to 30, more preferably from 0 to 10, and examples thereof include sulfamoylamino, N,N-dimethylaminosulfonylamino and N-n-octylaminosulfonylamino.

The alkyl- or aryl-sulfonylamino group is preferably a substituted or unsubstituted alkylsulfonylamino group having a carbon number of 1 to 30, more preferably from 1 to 10, or a substituted or unsubstituted arylsulfonylamino group having a carbon number of 6 to 30, more preferably from 6 to 10, and examples thereof include methylsulfonylamino, butylsulfonylamino, phenylsulfonylamino, 2,3,5-trichlorophenylsulfonylamino and p-methylphenylsulfonylamino.

The alkylthio group is preferably a substituted or unsubstituted alkylthio group having a carbon number of 1 to 30, more preferably from 1 to 10, and examples thereof include methylthio, ethylthio and n-hexadecylthio.

The arylthio group is preferably a substituted or unsubstituted arylthio group having a carbon number of 6 to 30, more preferably from 6 to 12, and examples thereof include phenylthio, p-chlorophenylthio and m-methoxyphenylthio.

The heterocyclic thio group is preferably a substituted or unsubstituted heterocyclic thio group having a carbon number of 2 to 30, and the heterocyclic moiety is preferably the heterocyclic moiety described above for the heterocyclic group. Examples of the heterocyclic thio group include 2-benzothiazolylthio and 1-phenyltetrazol-5-ylthio.

The sulfamoyl group is preferably a substituted or unsubstituted sulfamoyl group having a carbon number of 0 to 30, and examples thereof include N-ethylsulfamoyl, N-(3-dodecyloxypropyl)sulfamoyl, N,N-dimethylsulfamoyl, N-acetylsulfamoyl, N-benzoylsulfamoyl and N-(N′-phenylcarbamoyl)sulfamoyl.

The alkyl- or aryl-sulfino group is preferably a substituted or unsubstituted alkylsulfino group having a carbon number of 1 to 30, more preferably from 1 to 10, or a substituted or unsubstituted arylsulfino group having a carbon number 6 to 30, more preferably from 6 to 10, and examples thereof include methylsulfino, ethylsulfino, phenylsulfino and p-methylphenylsulfino.

The alkyl- or aryl-sulfonyl group is preferably a substituted or unsubstituted alkylsulfonyl group having a carbon number of 1 to 30, more preferably from 1 to 10, or a substituted or unsubstituted arylsulfonyl group having a carbon number of 6 to 30, more preferably from 6 to 10, and examples thereof include methylsulfonyl, ethylsulfonyl, phenylsulfonyl and p-methylphenylsulfonyl.

The acyl group is preferably a formyl group, a substituted or unsubstituted alkylcarbonyl group having a carbon number of 2 to 30, more preferably from 2 to 10, or a substituted or unsubstituted arylcarbonyl group having a carbon number 7 to 30, more preferably from 7 to 13, and examples thereof include acetyl, pivaloyl, 2-chloroacetyl, stearoyl, benzoyl and p-n-octyloxyphenylcarbonyl.

The aryloxycarbonyl group is preferably a substituted or unsubstituted aryloxycarbonyl group having a carbon number of 7 to 30, more preferably from 7 to 13, and examples thereof include phenoxycarbonyl, o-chlorophenoxycarbonyl, m-nitrophenoxycarbonyl and p-tert-butylphenoxycarbonyl.

The alkoxycarbonyl group is preferably a substituted or unsubstituted alkoxycarbonyl group having a carbon number of 2 to 30, more preferably from 2 to 10, and examples thereof include methoxycarbonyl, ethoxycarbonyl, tert-butoxycarbonyl and n-octadecyloxycarbonyl.

The carbamoyl group is preferably a substituted or unsubstituted carbamoyl group having a carbon number of 1 to 30, more preferably from 1 to 10, and examples thereof include carbamoyl, N-methylcarbamoyl, N,N-dimethylcarbamoyl, N,N-di-n-octylcarbamoyl and N-(methylsulfonyl)carbamoyl.

The aryl or heterocyclic azo group is preferably a substituted or unsubstituted arylazo group having a carbon number of 6 to 30, more preferably from 6 to 12, or a substituted or unsubstituted heterocyclic azo group having a carbon number of 3 to 30, more preferably from 3 to 10 (the heterocyclic moiety is preferably the heterocyclic moiety described above for the heterocyclic group), and examples thereof include phenylazo, p-chlorophenylazo and 5-ethylthio-1,3,4-thiadiazol-2-ylazo.

The imido group is preferably a substituted or unsubstituted imido group having a carbon number of 2 to 30, more preferably from 2 to 10, and examples thereof include N-succinimido and N-phthalimido.

The phosphino group is preferably a substituted or unsubstituted phosphino group having a carbon number of 2 to 30, more preferably from 2 to 15, and examples thereof include dimethylphosphino, diphenylphosphino and methylphenoxyphosphino. The phosphinyl group is preferably a substituted or unsubstituted phosphinyl group having a carbon number of 2 to 30, more preferably from 2 to 10, and examples thereof include phosphinyl, dioctyloxyphosphinyl and diethoxyphosphinyl.

The phosphinyloxy group is preferably a substituted or unsubstituted phosphinyloxy group having a carbon number of 2 to 30, more preferably from 2 to 10, and examples thereof include diphenoxyphosphinyloxy and dioctyloxyphosphinyloxy.

The phosphinylamino group is preferably a substituted or unsubstituted phosphinylamino group having a carbon number of 2 to 30, more preferably from 2 to 10, and examples thereof include dimethoxyphosphinylamino and dimethylaminophosphinylamino.

The silyl group is preferably a substituted or unsubstituted silyl group having a carbon number of 3 to 30, more preferably from 3 to 10, and examples thereof include trimethylsilyl, tert-butyldimethylsilyl and phenyldimethylsilyl.

Out of the functional groups above, those having a hydrogen atom may be deprived of the hydrogen atom and be further substituted by the above-described substituent. Examples of such a functional group include an alkylcarbonylaminosulfonyl group, an arylcarbonylaminosulfonyl group, an alkylsulfonylaminocarbonyl group and an arylsulfonylaminocarbonyl group, and specific examples thereof include a methylsulfonylaminocarbonyl group, a p-methylphenylsulfonylaminocarbonyl group, an acetylaminosulfonyl group and a benzoylaminosulfonyl group.

The resin as the component (B) may further have an acid-decomposable repeating unit other than the acid-decomposable repeating unit represented by formula (I′).

The acid-decomposable repeating unit other than the acid-decomposable repeating unit represented by formula (I′) is preferably a repeating unit represented by the following formula (II):

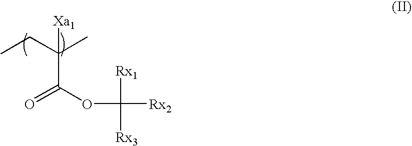

In formula (II), Xa₁ represents a hydrogen atom, an alkyl group, a cyano group or a halogen atom and is the same as Xa₁ in formula (I′).

Rx₁ to Rx₃ each independently represents an alkyl group or a cycloalkyl group. At least two members out of Rx₁ to Rx₃ may combine to form a cycloalkyl group.

The alkyl group of Rx₁ to Rx₃ is preferably a linear or branched alkyl group having a carbon number of 1 to 4, such as methyl group, ethyl group, n-propyl group, isopropyl group, n-butyl group, isobutyl group and tert-butyl group.

The cycloalkyl group of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The cycloalkyl group formed by combining at least two members out of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

An embodiment where Rx₁ is a methyl group or an ethyl group and Rx₂ and Rx₃ are combined to form the above-described monocyclic or polycyclic cycloalkyl group is preferred.

Specific preferred examples of the repeating unit having an acid-decomposable group are set forth below, but the present invention is not limited thereto.

(In the formulae, Rx represents H, CH₃, CF₃ or CH₂OH, and Rxa and Rxb each represents an alkyl group having a carbon number of 1 to 4.)

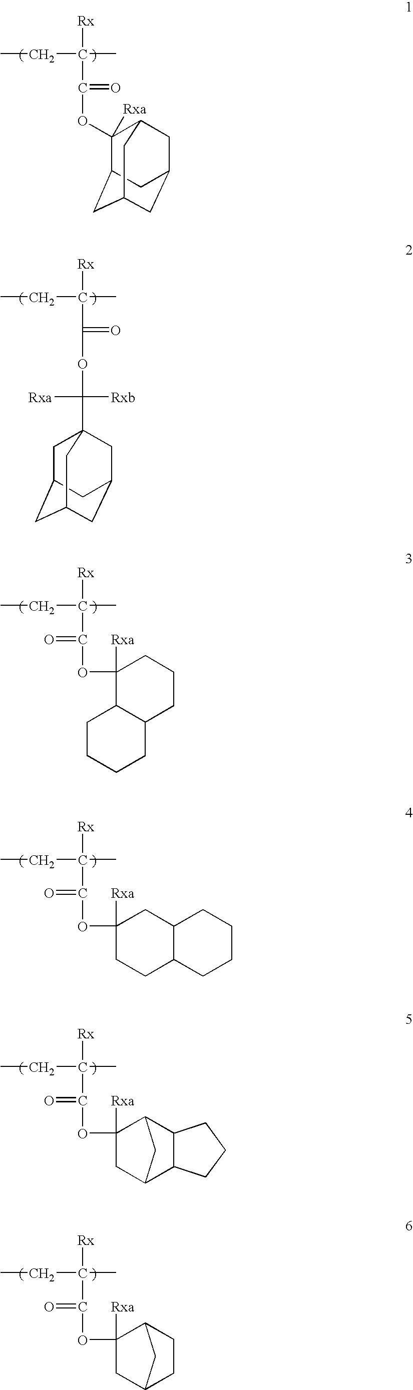

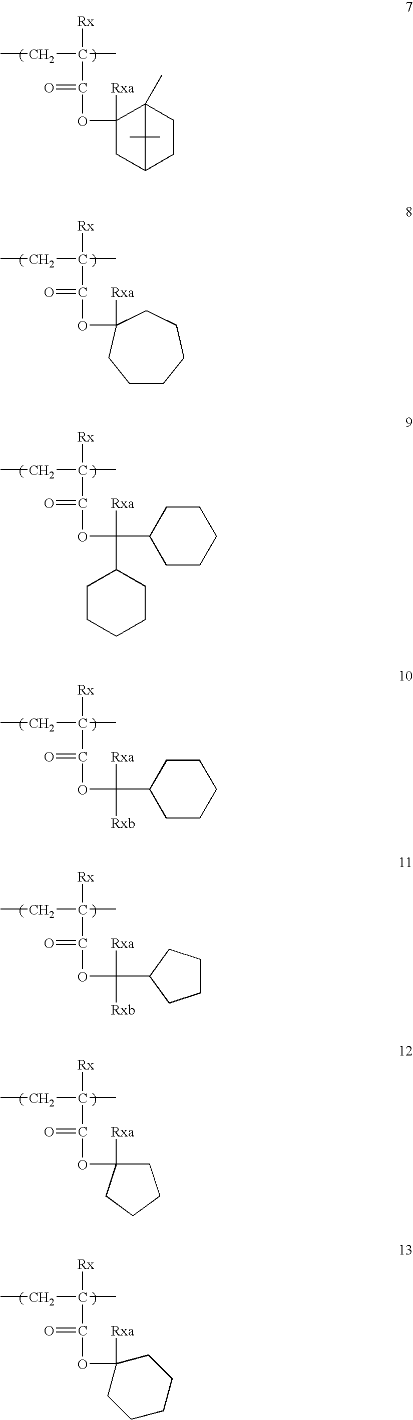

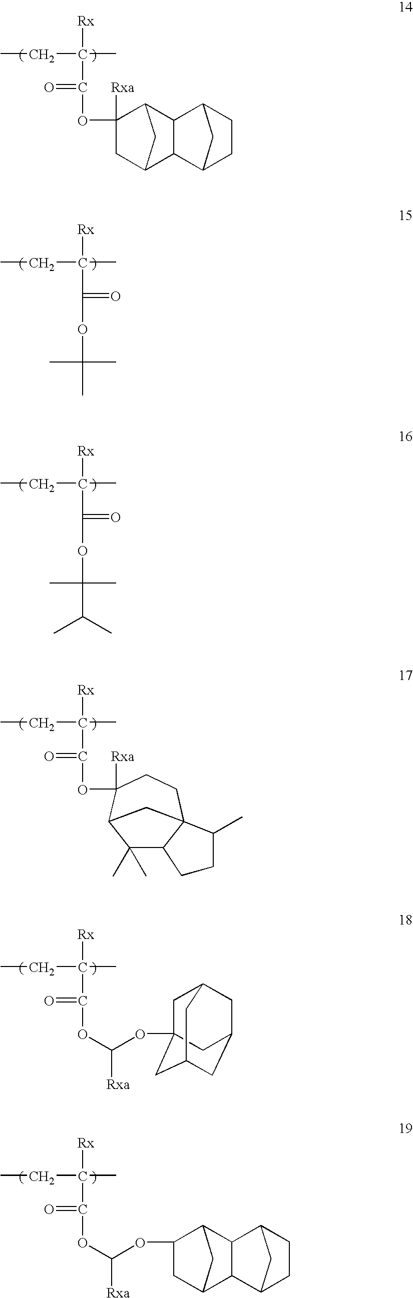

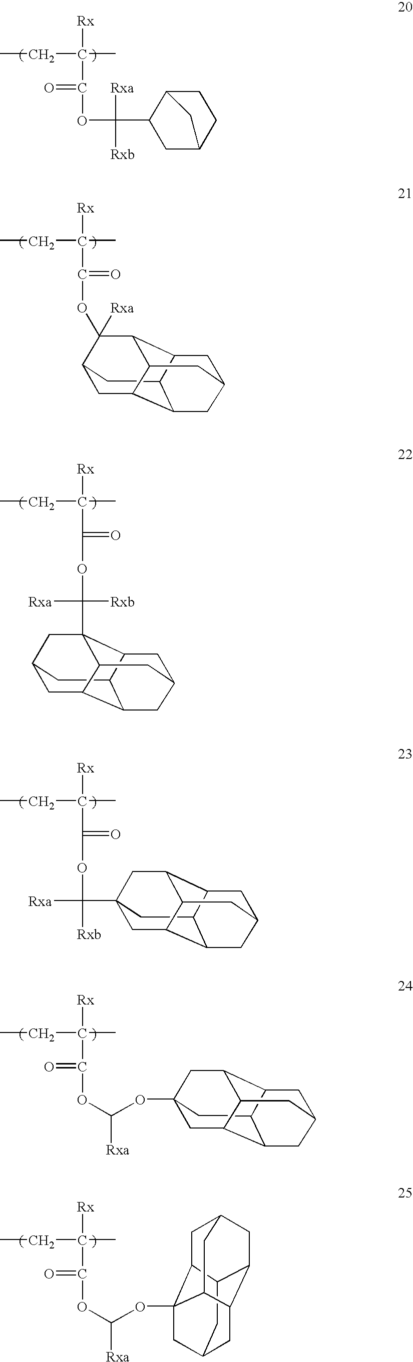

Among the repeating units represented by formula (II), preferred are repeating units 1, 2, 10, 11, 12, 13 and 14 in these specific examples.

In the case of using the acid-decomposable group-containing repeating unit represented by formula (I′) in combination with other acid-decomposable group-containing repeating units (preferably a repeating unit represented by formula (II)), the ratio between the acid-decomposable group-containing repeating unit represented by formula (I′) and the other acid-decomposable group-containing repeating unit is, in terms of the molar ratio, from 90:10 to 10:90, preferably from 80:20 to 20:80.

The content of all acid-decomposable group-containing repeating units in the resin as the component (B) is preferably from 20 to 50 mol %, more preferably from 25 to 45 mol %, based on all repeating units in the polymer.

The resin as the component (B) preferably further contains a repeating unit having at least one kind of a group selected from a lactone group, a hydroxyl group, cyano group and an alkali-soluble group.

The resin as the component (B) preferably contains a repeating unit having a lactone structure.

With respect to the lactone structure, any repeating unit may be used as long as it has a lactone structure, but the lactone structure is preferably a 5- to 7-membered ring lactone structure, and a repeating unit where another ring structure is condensed to the 5- to 7-membered ring lactone structure in the manner of forming a bicyclo or Spiro structure is preferred. The resin more preferably contains a repeating unit having a lactone structure represented by any one of the following formulae (LC1-1) to (LC1-16). The lactone structure may be bonded directly to the main chain. Among these lactone structures, preferred are (LC1-1), (LC1-4), (LC1-5), (LC1-6), (LC1-13) and (LC1-14). By virtue of using a specific lactone structure, the line edge roughness and development defect are improved.

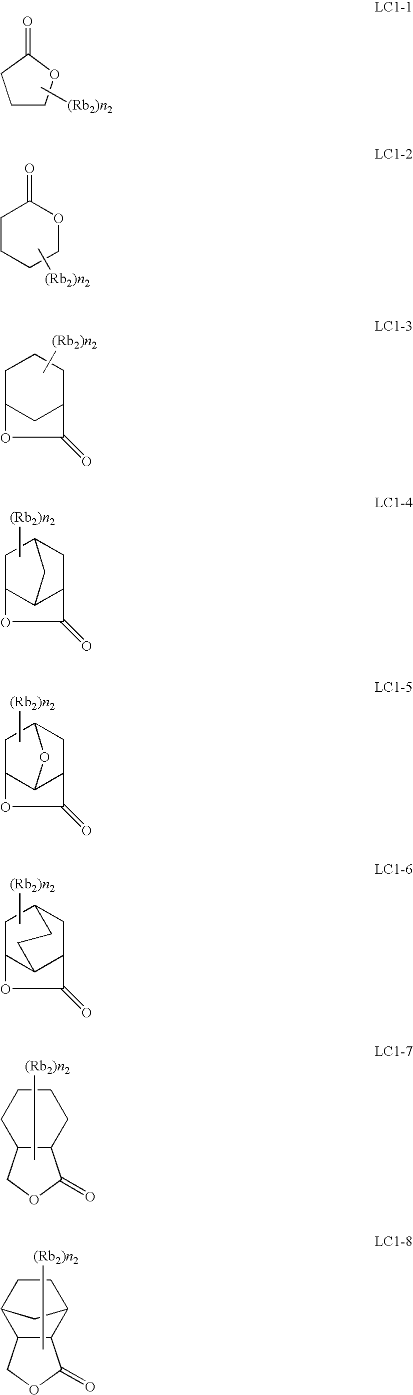

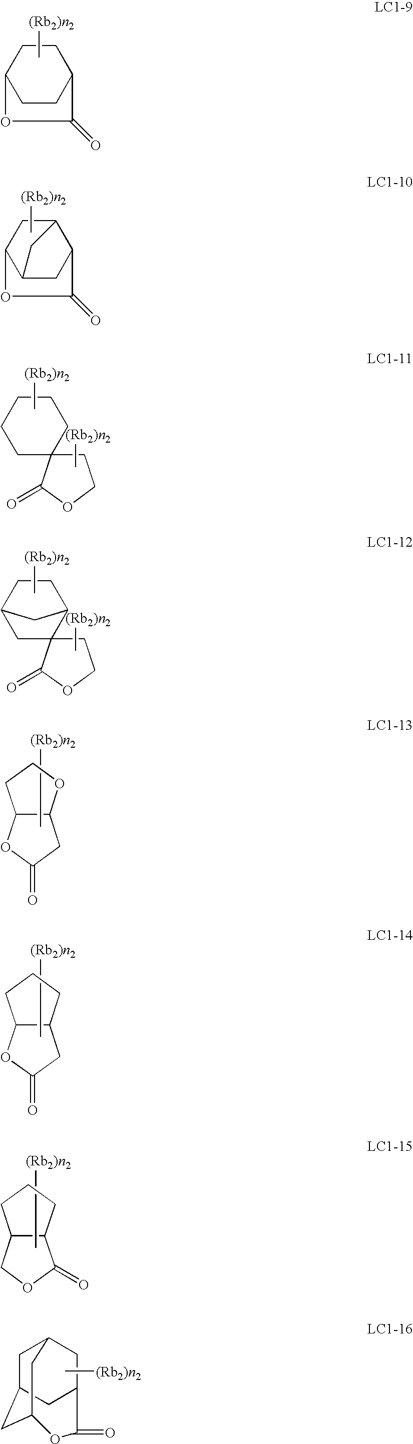

The lactone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 1 to 8, a carboxyl group, a halogen atom, a hydroxyl group, a cyano group, and an acid-decomposable group. Among these, an alkyl group having a carbon number of 1 to 4, a cyano group and an acid-decomposable group are more preferred. n₂ represents an integer of 0 to 4. When n₂ is an integer of 2 or more, the plurality of substituents Rb₂ may be the same or different and also, the plurality of substituents Rb₂ may combine with each other to form a ring.

The repeating unit having a lactone structure represented by any one of formulae (LC1-1) to (LC1-16) includes a repeating unit represented by the following formula (AI):

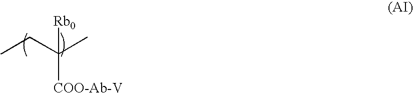

In formula (AI), Rb₀ represents a hydrogen atom, a halogen atom or an alkyl group having a carbon number of 1 to 4. Preferred examples of the substituent which the alkyl group of Rb₀ may have include a hydroxyl group and a halogen atom.

The halogen atom of Rb₀ includes a fluorine atom, a chlorine atom, a bromine atom and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, or a divalent group comprising a combination thereof, and is preferably a single bond or a divalent linking group represented by -Ab₁-CO₂—. Ab₁ represents a linear or branched alkylene group or a monocyclic or polycyclic cycloalkylene group and is preferably a methylene group, an ethylene group, a cyclohexylene group, an adamantylene group or a norbornylene group.

V represents a group having a structure represented by any one of formulae (LC1-1) to (LC1-16).

The repeating unit having a lactone structure usually has an optical isomer, but any optical isomer may be used. One optical isomer may be used alone or a mixture of a plurality of optical isomers may be used. In the case of mainly using one optical isomer, the optical purity (ee) thereof is preferably 90 or more, more preferably 95 or more.

The content of the repeating unit having a lactone structure is preferably from 15 to 60 mol %, more preferably from 20 to 50 mol %, still more preferably from 30 to 50 mol %, based on all repeating units in the polymer.

Specific examples of the repeating unit having a lactone structure are set forth below, but the present invention is not limited thereto.

(In the formulae, Rx is H, CH₃, CH₂OH or CF₃.)

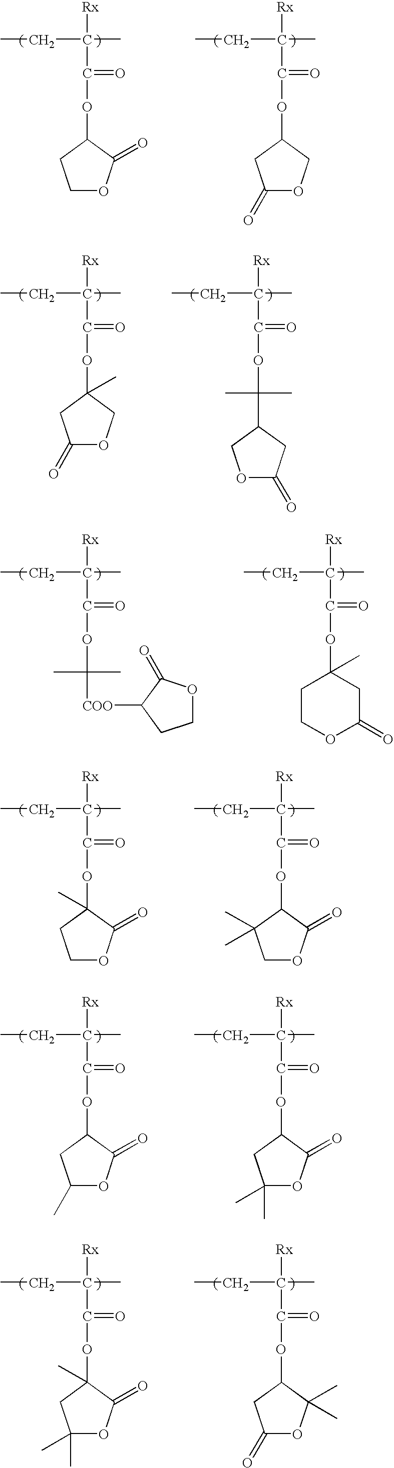

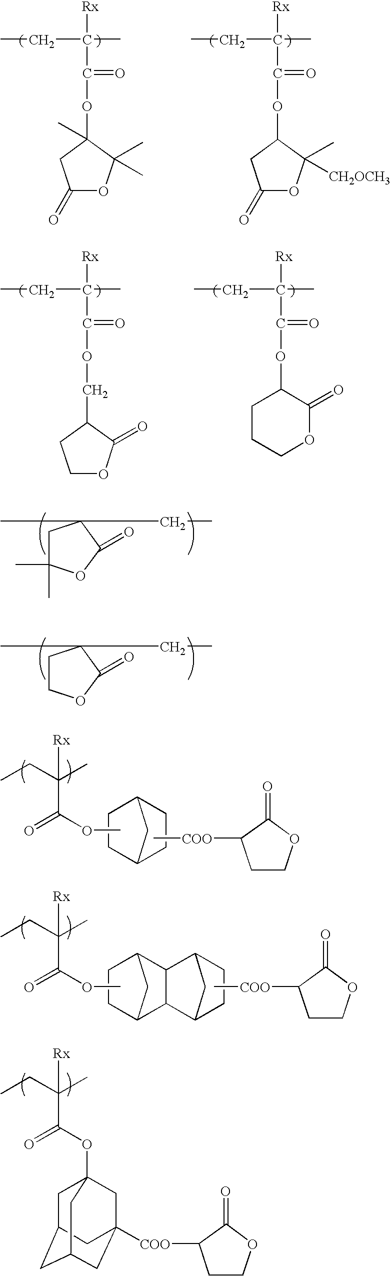

(In the formulae, Rx is H, CH₃, CH₂OH or CF₃.)

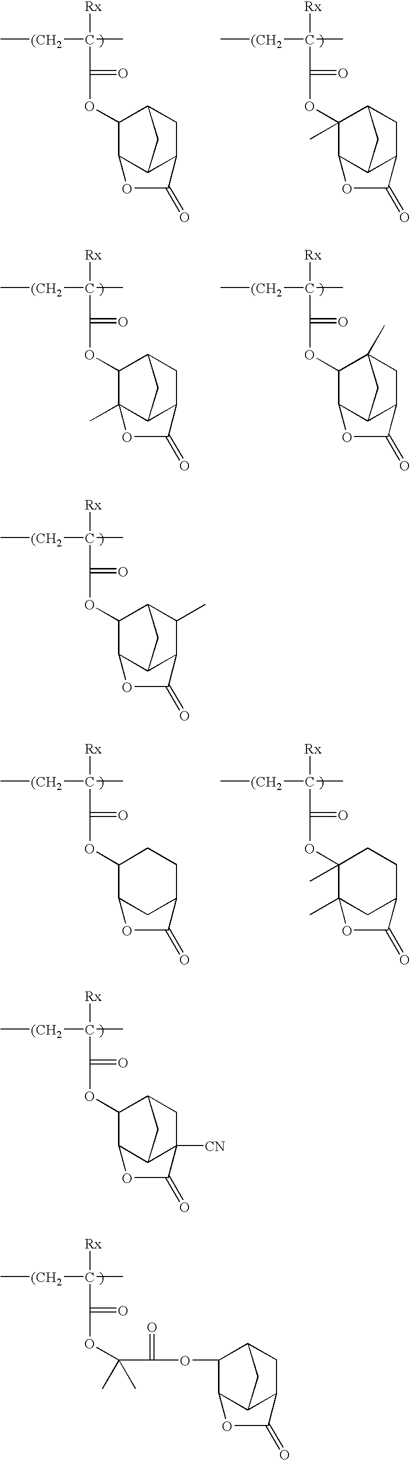

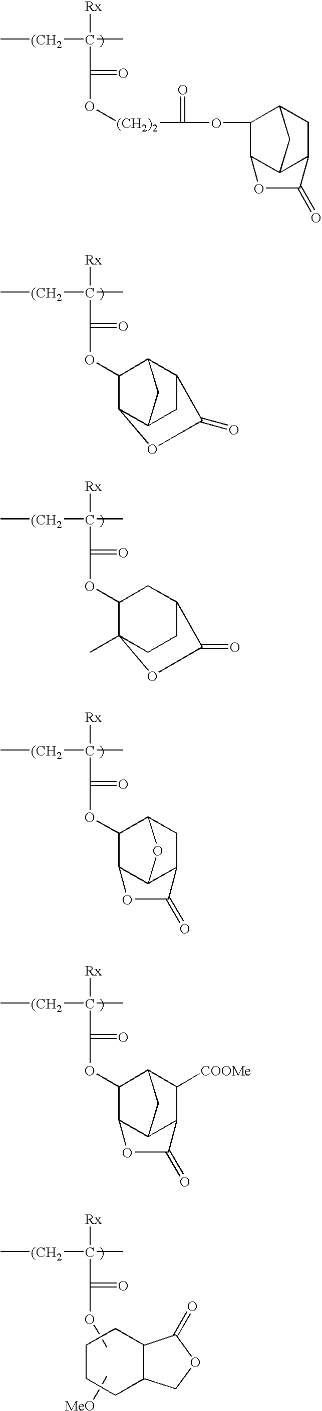

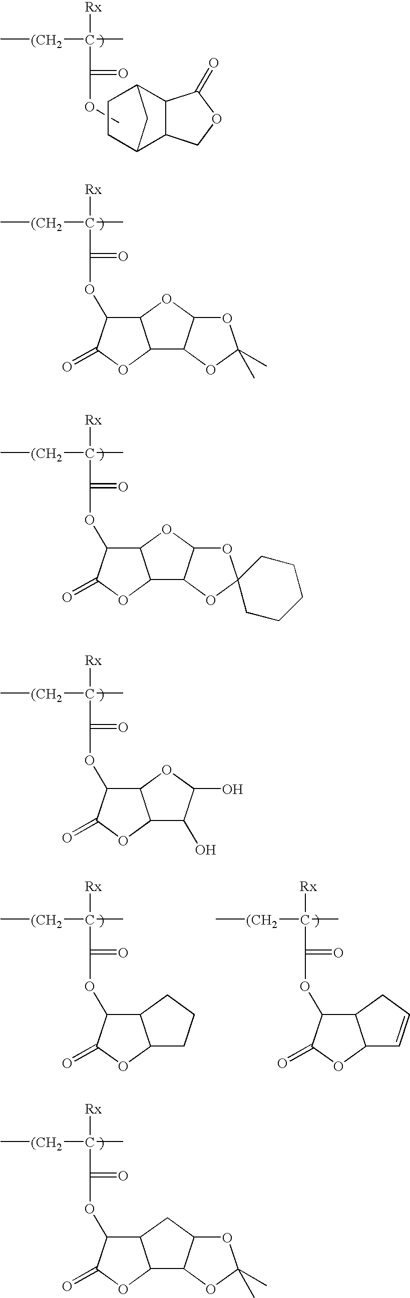

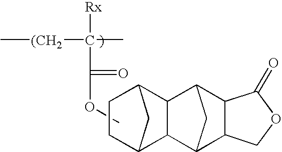

(In the formulae, Rx is H, CH₃, CH₂OH or CF₃.)

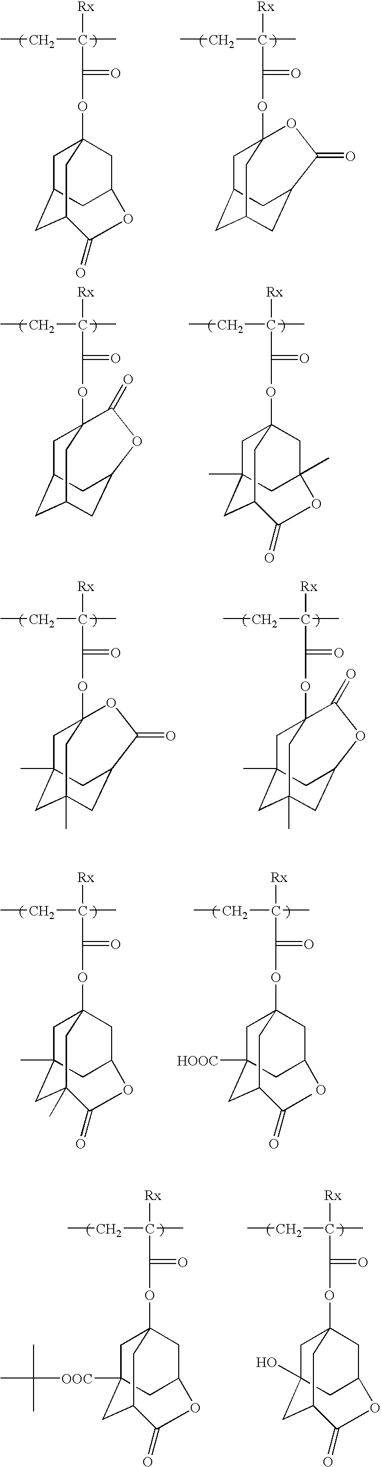

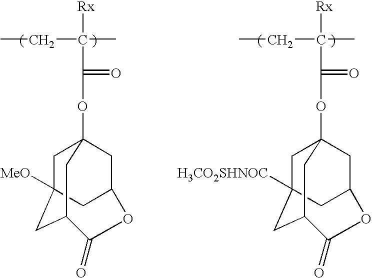

The repeating unit having a particularly preferred lactone structure includes the repeating units shown below. By selecting an optimal lactone structure, the pattern profile and defocus latitude depended on line pitch are improved.

(In the formulae, Rx is H, CH₃, CH₂OH or CF₃.)

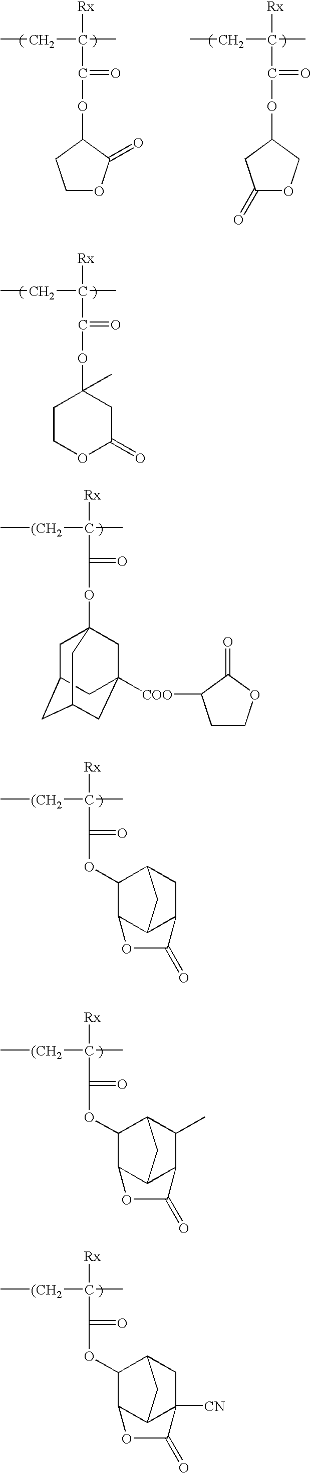

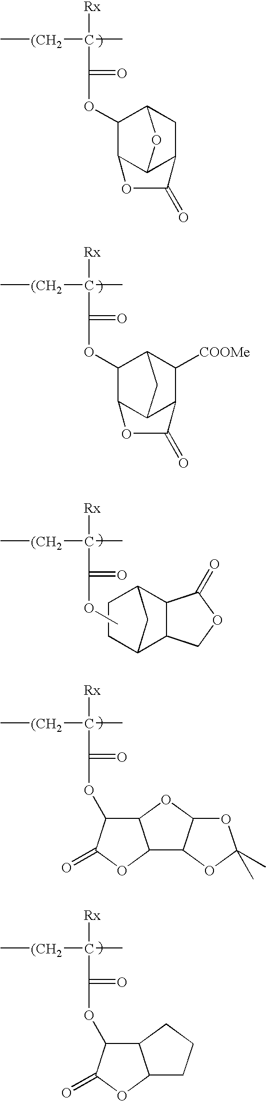

The resin as the component (B) preferably contains a repeating unit having a hydroxyl group or a cyano group. By virtue of this repeating unit, the adhesion to substrate and the affinity for developer are enhanced. The repeating unit having a hydroxyl group or a cyano group is preferably a repeating unit having an alicyclic hydrocarbon structure substituted by a hydroxyl group or a cyano group. The alicyclic hydrocarbon structure in the alicyclic hydrocarbon structure substituted by a hydroxyl group or a cyano group is preferably an adamantyl group, a diamantyl group or a norbornane group.

The alicyclic hydrocarbon structure substituted by a hydroxyl group or a cyano group is preferably a partial structure represented by any one of the following formulae (VIIa) to (VIId):

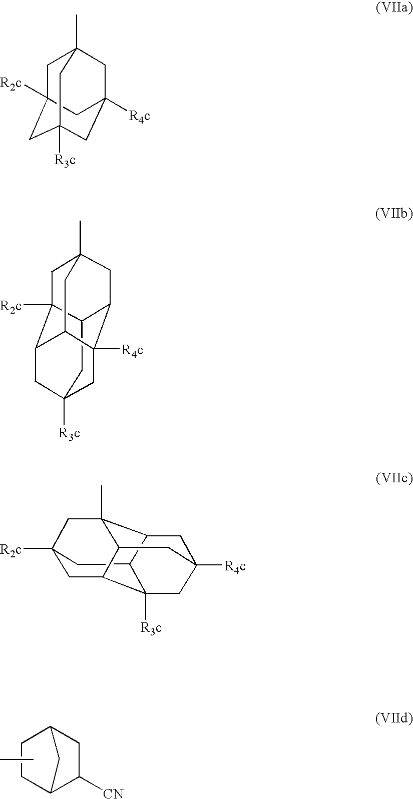

In formulae (VIIa) to (VIIc), R_{2c} to R_{4c}, each independently represents a hydrogen atom, a hydroxyl group or a cyano group, provided that at least one of R_{2c} to R_{4c} represents a hydroxyl group or a cyano group. A structure where one or two members out of R_{2c} to R_{4c} are a hydroxyl group with the remaining being a hydrogen atom is preferred. In formula (VIIa), it is more preferred that two members out of R_{2c} to R_{1c} are a hydroxyl group and the remaining is a hydrogen atom.

The repeating unit having a partial structure represented by any one of formulae (VIIa) to (VIId) includes repeating units represented by the following formulae (AIIa) to (AIId):

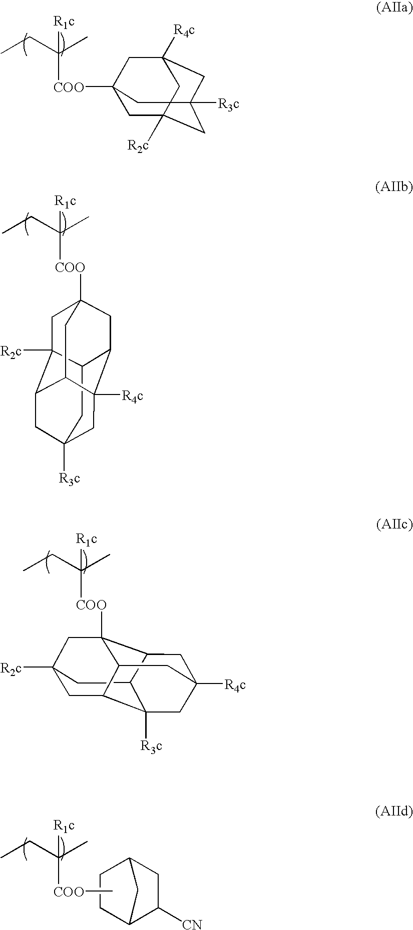

In formulae (AIIa) to (AIId), R_{1c} represents a hydrogen atom, a methyl group, a trifluoromethyl group or a hydroxymethyl group.

R_{2c} to R_{4c} have the same meanings as R_{2c} to R_{4c} in formulae (VIIa) to (VIIc).
The content of the repeating unit having an alicyclic hydrocarbon structure substituted by a hydroxyl group or a cyano group is preferably from 5 to 40 mol %, more preferably from 5 to 30 mol %, still more preferably from 10 to 25 mol %, based on all repeating units in the polymer.

Specific examples of the repeating unit having a hydroxyl group or a cyano group are set forth below, but the present invention is not limited thereto.

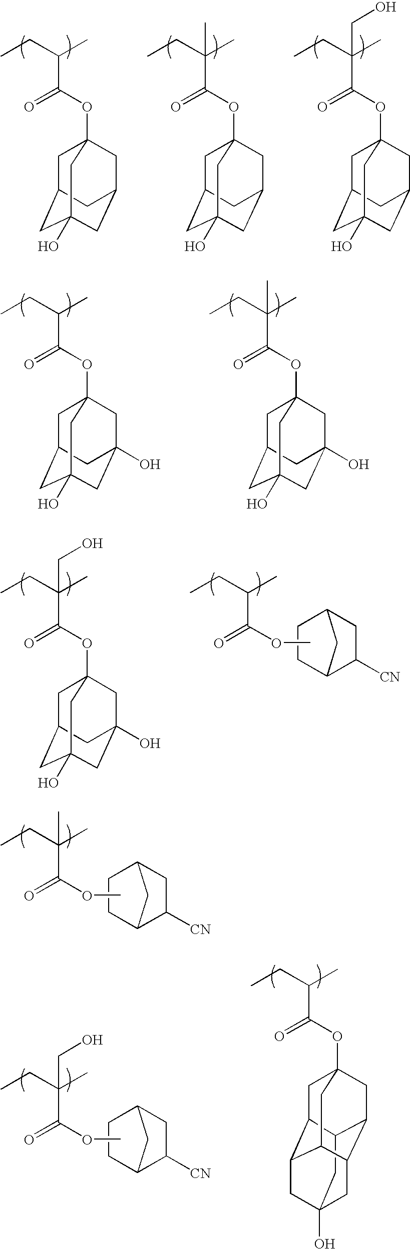

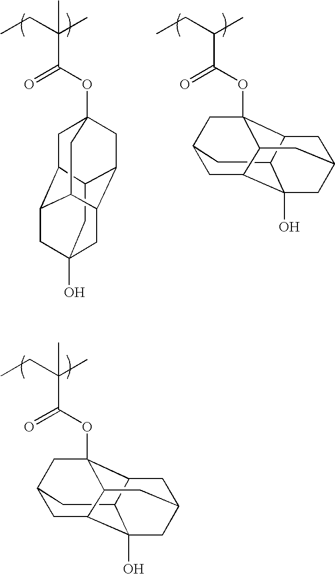

The resin as the component (B) preferably contains a repeating unit having an alkali-soluble group. The alkali-soluble group includes a carboxyl group, a sulfonamide group, a sulfonylimide group, a bisulfonylimide group, and an aliphatic alcohol with the α-position being substituted by an electron-withdrawing group, such as hexafluoroisopropanol. The resin more preferably contains a repeating unit having a carboxyl group. By virtue of containing a repeating unit having an alkali-soluble group, the resolution increases in the usage of forming contact holes. As for the repeating unit having an alkali-soluble group, all of a repeating unit where an alkali-soluble group is directly bonded to the resin main chain, such as repeating unit by an acrylic acid or a methacrylic acid, a repeating unit where an alkali-soluble group is bonded to the resin main chain through a linking group, and a repeating unit where an alkali-soluble group is introduced into the polymer chain terminal by using an alkali-soluble group-containing polymerization initiator or chain transfer agent at the polymerization, are preferred. The linking group may have a monocyclic or polycyclic hydrocarbon ring structure. In particular, a repeating unit by an acrylic acid or a methacrylic acid is preferred.

The content of the repeating unit having an alkali-soluble group is preferably from 1 to 20 mol %, more preferably from 3 to 15 mol %, still more preferably from 5 to 10 mol %, based on all repeating units in the polymer.

Specific examples of the repeating unit having an alkali-soluble group are set forth below, but the present invention is not limited thereto.

(In the formulae, Rx is H, CH₃, CF₃ or CH₂OH.)

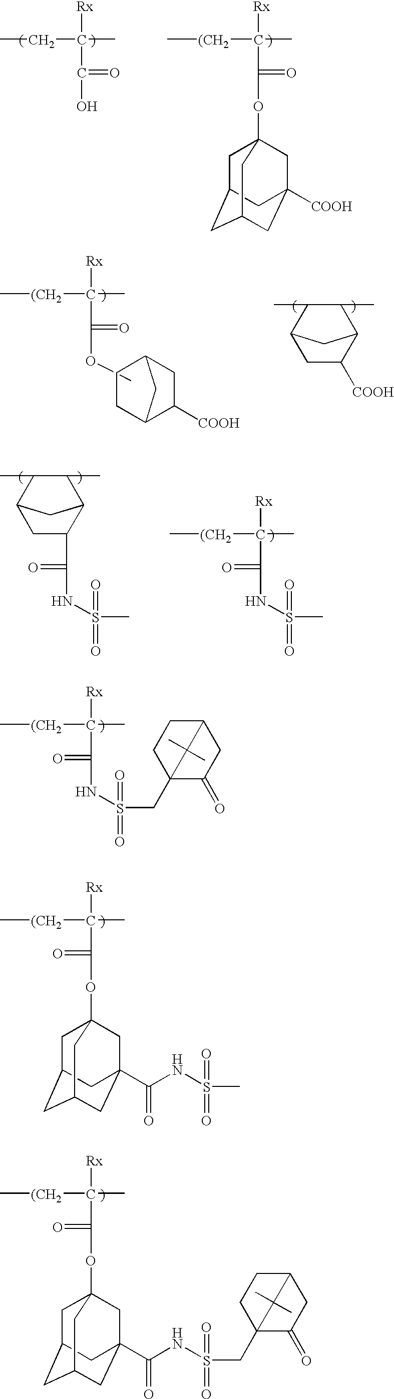

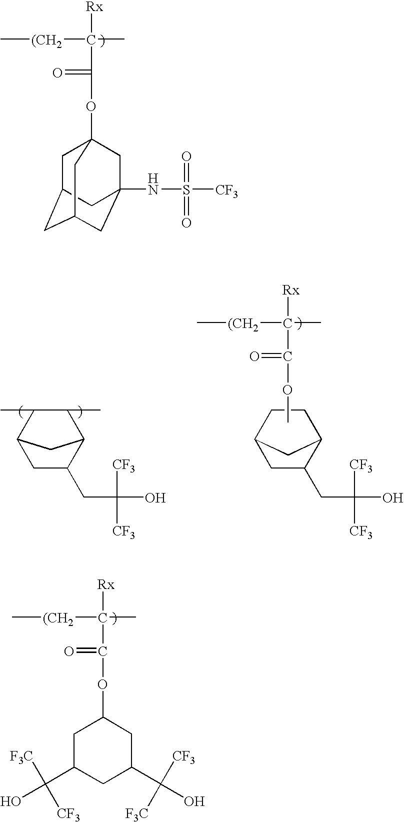

The repeating unit having at least one kind of a group selected from a lactone group, a hydroxyl group, a cyano group and an alkali-soluble group is more preferably a repeating unit having at least two groups selected from a lactone group, a hydroxyl group, a cyano group and an alkali-soluble group, still more preferably a repeating unit having a cyano group and a lactone group, yet still more preferably a repeating unit having a structure where a cyano group is substituted to the lactone structure of LCI-4 above.

The resin as the component (B) may further contain a repeating unit having an alicyclic hydrocarbon structure and not exhibiting acid decomposability. By containing such a repeating unit, dissolving out of low molecular components from the resist film into the immersion liquid at the immersion exposure can be reduced. Examples of this repeating unit include 1-adamantyl(meth)acrylate, diamantyl(meth)acrylate, tricyclodecanyl(meth)acrylate, and cyclohexyl(meth)acrylate.

In the case of using the resin as the component (B) for a positive photosensitive composition subjected to irradiation with KrF excimer laser light, electron beam, X-ray or high energy beam at a wavelength of 50 nm or less (e.g., EUV), the resin as the component (B) preferably contains a repeating unit of formula (I′) and further a repeating unit having a hydroxystyrene structure. The repeating unit having a hydroxystyrene structure includes an o-, m- or p-hydroxystyrene and/or a hydroxystyrene protected by an acid-decomposable group. The hydroxystyrene repeating unit protected by an acid-decomposable group is preferably a 1-alkoxyethoxystyrene or a tert-butylcarbonyloxystyrene. In addition to the repeating unit represented by formula (I′) and the repeating unit having a hydroxystyrene structure, the resin may further contain a repeating unit represented by formula (II).

Specific examples of the resin containing a repeating unit having a hydroxystyrene structure and a repeating unit represented by formula (I′) for use in the present invention are set forth below, but the present invention is not limited thereto. In specific examples, Xa₁ represents a hydrogen atom, an alkyl group, a cyano group or a halogen atom.

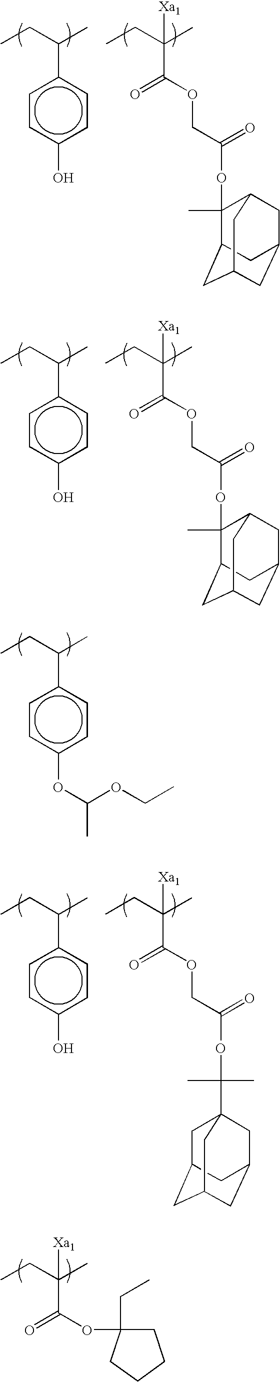

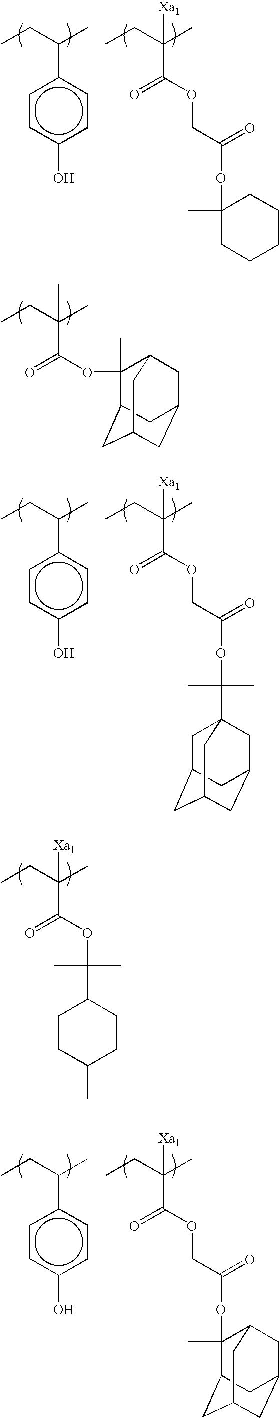

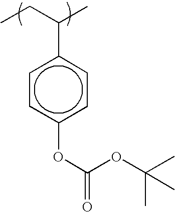

The resin as the component (B) may further contain, in addition to the above-described repeating structural units, various repeating structural units for the purpose of controlling dry etching resistance, suitability for standard developer, adhesion to substrate, resist profile and properties generally required of the resist, such as resolving power, heat resistance and sensitivity.

Examples of such a repeating structural unit include, but are not limited to, repeating structural units corresponding to the monomers described below.

By virtue of such a repeating structural unit, the performance required of the resin as the component (B), particularly,

(1) solubility in coating solvent,

(2) film-forming property (glass transition point),

(3) alkali developability,

(4) film loss (selection of hydrophilic, hydrophobic or alkali-soluble group),

(5) adhesion of unexposed area to substrate,

(6) dry etching resistance

and the like, can be subtly controlled.

Examples of the monomer include a compound having one addition-polymerizable unsaturated bond selected from acrylic acid esters, methacrylic acid esters, acrylamides, methacrylamides, allyl compounds, vinyl ethers and vinyl esters.

Other than these, an addition-polymerizable unsaturated compound copolymerizable with the monomers corresponding to the above-described various repeating structural units may be copolymerized.

In the resin as the component (B), the molar ratio of respective repeating structural units contained is appropriately determined to control the dry etching resistance of resist, suitability for standard developer, adhesion to substrate, resist profile and performances generally required of the resist, such as resolving power, heat resistance and sensitivity.

In the case of using the positive photosensitive composition of the present invention for exposure with ArF, the resin as the component (B) preferably has no aromatic group in view of transparency to ArF light.

The resin as the component (B) is preferably a resin where all repeating units are composed of a (meth)acrylate-based repeating unit. In this case, the repeating units may be all a methacrylate-based repeating unit, all an acrylate-based repeating unit, or all a mixture of methacrylate-based repeating unit/acrylate-based repeating unit, but the content of the acrylate-based repeating unit is preferably 50 mol % or less based on all repeating units.

The resin is more preferably a copolymerization polymer containing from 20 to 50 mol % of an acid decomposable group-containing (meth)acrylate-based repeating unit represented by formula (I′), from 20 to 50 mol % of a (meth)acrylate-based repeating unit having a lactone structure, from 5 to 30 mol % of a (meth)acrylate-based repeating unit having an alicyclic hydrocarbon structure substituted by a hydroxyl group or a cyano group, and from 0 to 20 mol % of other (meth)acrylate-based repeating units.

The resin as the component (B) for use in the present invention is a resin having a dispersity of 1.5 or less. The production method of the resin having a dispersity of 1.5 or less includes known living radical polymerization, living anionic polymerization, living cationic polymerization, and fractionation by a solvent. Among these, living radical polymerization is preferred. The living radical polymerization as used herein indicates radical polymerization where the growth terminal is in a state of radicals being released or recombined during the polymerization and an apparent termination reaction does not proceed. Under such conditions, the dispersity (the ratio of weight average molecular weight to number average molecular weight) becomes very small as compared with that in normal radical polymerization. The living radical polymerization is more preferred than other methods because of the following reason. The living anionic polymerization and living cationic polymerization are disadvantageous in that no-water conditions or deoxygenation conditions are required, causing a rise of the production cost, and a polymer having a group such as hydroxyl group or carboxyl group cannot be produced. On the other hand, unlike other living polymerization, the living radical polymerization does not require strict dehydrated conditions and favors very low production cost.

Examples of the living radical polymerization include a method using a chain transfer agent, and a method of performing the polymerization in the presence of a metal complex catalyst (a transition metal catalyst with the center metal being Fe, Ru, Cu, Ni or the like) and a halogen atom-containing compound. Of these, a method using a chain transfer agent is preferred.

Examples of the chain transfer agent in the living radical polymerization using a chain transfer agent include a sulfur-containing compound, a nitrogen-containing compound (e.g., nitroxyl-based compound), and an iodine-containing alkyl (e.g., 2-iodoperfluoropropane). Out of these chain transfer agents, when a sulfur-containing compound is used, the dispersity of the resin can be effectively reduced and at the same time, the metal content in the resin can be decreased.

The sulfur-containing compound as the chain transfer agent is preferably a compound represented by formula (CT). By virtue of this structure, the dispersity of the resin for use in the present invention can be more effectively reduced.

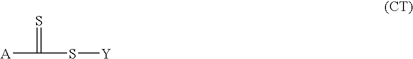

In formula (CT), A represents an alkyl group, a cycloalkyl group, an alkoxy group, an alkylthio group, an arylthio group, a heterocyclic thio group, an aryl group or a heterocyclic group.

Y represents a group capable of releasing a radical.

The alkyl group in A is preferably an alkyl group having a carbon number of 1 to 20 (e.g., methyl, ethyl, n-propyl, isopropyl, n-butyl, tert-butyl, sec-butyl, n-octyl) excluding the carbon number of the substituent, and most preferably an alkyl group having a carbon number of 1 to 10 excluding the carbon number of the substituent. The cycloalkyl group in A is preferably a monocyclic or polycyclic cycloalkyl group having a carbon number of 3 to 20 (e.g., cyclopentyl, cyclohexyl, cycloheptyl, norbornyl, adamantyl) excluding the carbon number of the substituent, and most preferably a monocyclic or polycyclic cycloalkyl group having a carbon number of 3 to 15 excluding the carbon number of the substituent. The aryl group in A is preferably an aryl group having a carbon number of 6 to 30 (e.g., phenyl, naphthyl, anthranyl) excluding the carbon number of the substituent, and most preferably an aryl group having a carbon number of 6 to 18. The heterocyclic group in A includes a 5- to 7-membered, saturated or unsaturated, aromatic or non-aromatic, monocyclic or condensed heterocyclic group having a carbon number of 3 to 30 and is preferably a heterocyclic group having ring-constituting atoms selected from carbon atom, nitrogen atom and sulfur atom and containing at least one heteroatom selected from the group consisting of nitrogen atom, oxygen atom and sulfur atom, more preferably a 5- or 6-membered aromatic heterocyclic group having a carbon number of 3 to 30. Examples of the heterocyclic group include 2-furyl, 2-thienyl, 2-pyridyl, 4-pyridyl, 2-pyrimidinyl, 2-benzothiazolyl, pyrrol-1-yl, imidazol-1-yl, pyrazol-1-yl, 1,2,3-triazol-1-yl, 1,2,4-triazol-1-yl, 1,2,4-triazol-4-yl, and indol-1-yl.

Examples of the substituent which A may have include an alkyl group, a cycloalkyl group, a halogen atom, an alkoxy group, an alkoxycarbonyl group, and a cyano group.

Y represents a group capable of releasing a radical. The term “a group capable of releasing a radical” means a group where, as shown below, Y becomes a radical after the reaction between a free radical (R) and a compound represented by formula (CT) and can be liberated from the structure of formula (CT).

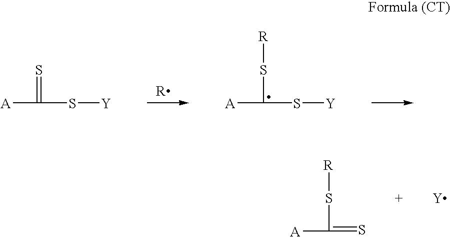

Formula (CT) is preferably a structure represented by formula (IIa) or (IIb). By virtue of using a chain transfer agent having such a structure, a narrow dispersive polymer having high transmittance at 193 nm can be produced.

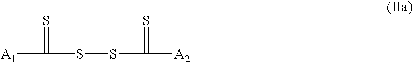

In formula (IIa), A₁ and A₂ each has the same meaning as A in formula (CT).

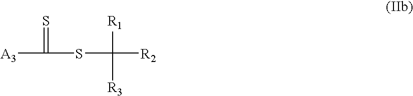

In formula (IIb), A₃ has the same meaning as A in formula (CT). R₁, R₂ and R₃ each independently represents an alkyl group, a cycloalkyl group, an aryl group, an alkoxycarbonyl group or a cyano group.

Specific examples of the compound represented by formula (CT) are set forth below, but the present invention is not limited thereto.

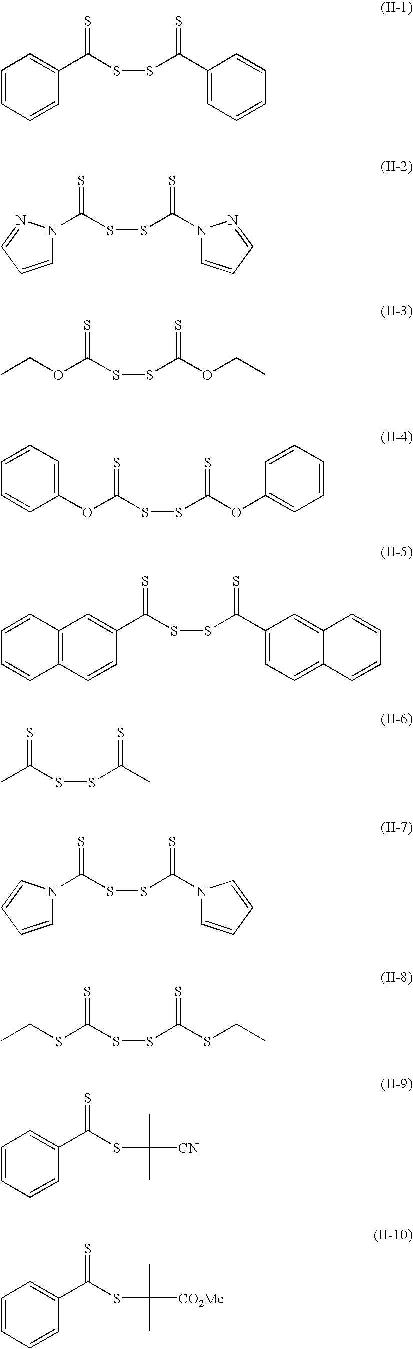

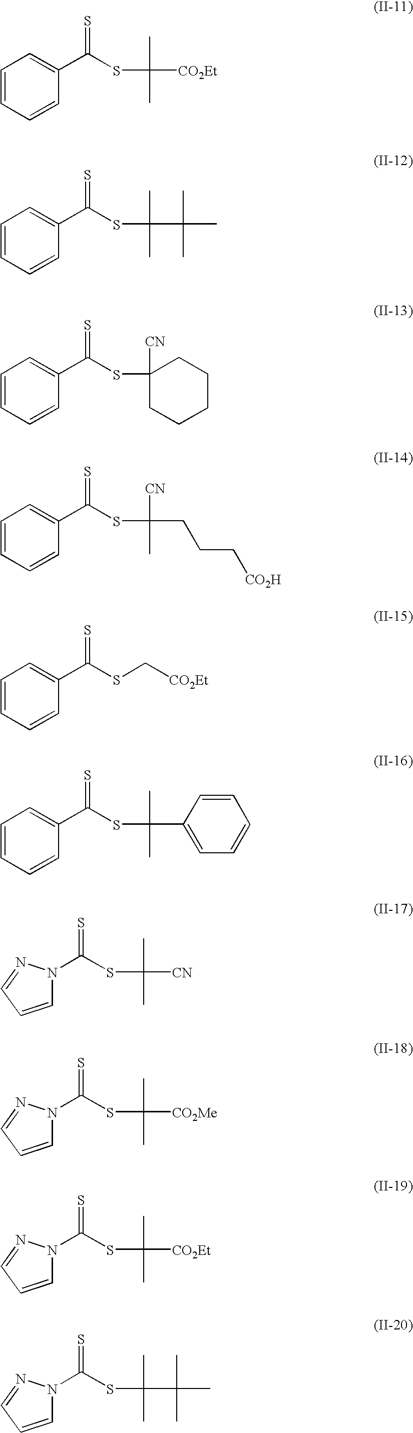

As for the synthesis method of the compound represented by formula (CT), a known method may be used. More specifically, examples of the synthesis method include a method of reacting a nucleophilic agent with carbon disulfide to synthesize a dithiocarboxylic acid and then reacting it with an alkylating agent (Method 1), and a method of reacting a dithiocarboxylic acid with an oxidizing agent to synthesize bis(thiocarbonyl) disulfide and then reacting it with a polymerization initiator to synthesize a dithioester (Method 2).

Living radical polymerization using the chain transfer agent of formula (CT) is described below. The polymerization method includes a method of performing the polymerization by heating a solution containing monomers, a polymerization initiator and a chain transfer agent of formula (CT) (batch polymerization), and a method of performing the polymerization while adding a solution containing monomers to a heated solution (dropping polymerization), but a dropping polymerization method is preferred in view of production stability. The monomers, polymerization initiator and chain transfer agent may be separately added to the reaction system or may be added as a mixture. In the case of separately adding these to the reaction system, the addition time may be the same or different, and the addition initiating time may be staggered. In the present invention, the reaction system may be a reaction solvent itself or may be a reaction solvent where some selected from monomers, a polymerization initiator and a chain transfer agent are previously added. More specifically, in the present invention, monomers may be polymerized using a reaction solvent itself as the reaction system while adding monomers, a polymerization initiator and a chain transfer agent thereto, or after preparing a reaction system by previously adding some selected from monomers, a polymerization initiator and a chain transfer agent to a reaction solvent, monomers may be polymerized while adding the remaining monomers, polymerization initiator and chain transfer agent thereto. In particular, it is preferred to prepare a reaction system by adding the entire amount of a chain transfer agent used and depending on the case, adding some of monomers and a polymerization initiator and then add the remaining monomers and polymerization initiator thereto. At the addition, a monomer, polymerization initiator or a chain transfer agent is preferably dissolved in a reaction solvent and added in the form of a solution. Examples of the reaction solvent include ethers such as tetrahydrofuran, 1,4-dioxane and diisopropyl ether, ketones such as methyl ethyl ketone, methyl isobutyl ketone and cyclohexanone, an ester solvent such as ethyl acetate and butyl acetate, an amide solvent such as dimethylformamide, dimethylacetamide and N-methylpyrrolidinone, and a solvent capable of dissolving the composition of the present invention, which is described later, such as propylene glycol monomethyl ether acetate and propylene glycol monomethyl ether. These solvents may be used alone or as a mixture. It is more preferred to perform the polymerization by using the same solvent as the solvent used in the resist composition of the present invention. The polymerization reaction is preferably performed in an inert gas atmosphere such as nitrogen and argon.

As for the polymerization initiator, a commercially available radical initiator (e.g., azo-based initiator, peroxide) can be used. The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile and dimethyl 2,2′-azobis(2-methylpropionate). The polymerization initiator may be used alone or as a mixture.

As for the monomer, monomers corresponding to the repeating units of a polymer intended to produce are used.

For example, in the case where the polymer intended to produce is an acid-decomposable resin described later, monomers corresponding to the repeating units of the acid-decomposable resin intended to produce are used.

After the completion of reaction, the reaction product is charged into a solvent, and the desired polymer is recovered by a method such as powder or solid recovery. The reaction concentration is from 5 to 50 mass %, preferably from 10 to 30 mass %. The reaction temperature varies depending on the decomposition efficiency of the radical initiator used and is difficult to univocally specify but if the reaction temperature is too low, the monomer conversion decreases and the reaction takes a long time, giving rise to bad efficiency, whereas if it is excessively high, the polymerization cannot be controlled. Therefore, the reaction temperature is preferably from a 10 hours half-life temperature of the initiator used to a 10 minutes half-life temperature, more preferably from 9 hours half-life temperature to a 20 minutes half-life temperature. For example, in the case of using azobisisobutyronitrile as the initiator, the reaction temperature is preferably from 50 to 100° C., and most preferably from 60 to 90° C. The polymerization initiator is preferably used in an amount of 0.01 to 10.0 molar equivalents, most preferably from 0.20 to 5.0 molar equivalents, based on the chain transfer agent, because if the amount used is too small based on the chain transfer agent, the reaction speed becomes extremely low, whereas if it is excessively high, the polymerization reaction can be hardly controlled. As for the chain transfer agent, a chain transfer agent represented by formula (CT) is used. The chain transfer agent may be used alone or as a mixture. The amount of the chain transfer agent used varies depending on the target number average molecular weight of the polymer and cannot be univocally determined but approximately, the amount used is preferably from 0.01 to 50.0 molar equivalents, more preferably from 0.1 to 20.0 molar equivalents, based on the molar number of all monomers.

The weight average molecular weight of the resin (B) for use in the present invention is preferably from 1,000 to 200,000, more preferably from 3,000 to 20,000, and most preferably from 5,000 to 15,000, in terms of polystyrene by the GPC method. When the weight average molecular weight is from 1,000 to 200,000, the heat resistance, dry etching resistance and developability can be prevented from deterioration and also, deterioration in the film-forming property due to high viscosity can be prevented.

The dispersity (molecular weight distribution) of the polymer obtained by the polymerization method of the present invention is lower than that of a normal radical polymerization product. By virtue of this, the resolution and resist profile are excellent, the side wall of the resist pattern is smooth, and the property in terms of roughness is improved. The dispersity of the polymer for use in the present invention is 1.5 or less, preferably from 1.0 to less than 1.40, more preferably from 1.0 to less than 1.30. As the molecular weight distribution is smaller, the side wall of the resist pattern is smoother, and the property in terms of roughness is more improved.

In the present invention, the dispersity is measured using GPC (gel permeation chromatography). The gel packed in the column used for GPC is preferably a gel having an aromatic compound in the repeating unit, and examples thereof include a gel comprising a styrene-divinylbenzene copolymer. Two to six columns are preferably connected and used. The solvent used includes an ether-based solvent such as tetrahydrofuran, and an amide-based such as N-methylpyrrolidinone, but an ether-based solvent such as tetrahydrofuran is preferred. The measurement is preferably performed at a solvent flow velocity of 0.1 to 2 mL/min, most preferably from 0.5 to 1.5 mL/min When the measurement is performed in this range, the measurement can be performed more efficiently without imposing a load on the apparatus. The measurement temperature is preferably from 10 to 50° C., and most preferably from 20 to 40° C.

In more detail, the dispersity of the present invention is measured under the following conditions.

Apparatus: HLC-8220GPC (manufactured by Tosoh Corp.)

Detector: Differential refractometer (RI detector)

Precolumn: TSKGUARDCOLUMN MP(XL), 6 mm×40 mm (manufactured by Tosoh Corp.)

Sample-side column: The following column was used, and four columns were directly connected (all manufactured by Tosoh Corp.).
TSK-GEL Multipore-HXL-M 7.8 mm×300 mm

Reference-side column: Same as the sample-side column.

Thermostatic bath temperature: 40° C.

Moving bed: Tetrahydrofuran

Flow rate of sample-side moving bed: 1.0 mL/min

Flow rate of reference-side moving bed: 0.3 mL/min

Sample concentration: 0.1 wt %

Amount of sample injected: 100 μL

Data sampling time: 16 to 46 minutes after sample injection

Sampling pitch: 300 msec

In the polymer obtained by the polymerization method of the present invention, a substituent (dithioester group) derived from the chain transfer agent, represented by formula (III), sometimes remains at the terminal.

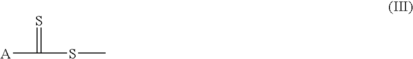

In formula (III), A has the same meaning as A in formula (CT).

If this polymer is directly used as a resist material, a bad pattern profile may result due to bad transmittance. Therefore, the dithioester group derived from the chain transfer agent needs to be removed. The method for removal includes a method of replacing the dithioester group, after the completion of polymerization, by adding a radical generator and if desired, a chain transfer agent (e.g., thiol, disulfide). At this time, there are a method of adding a radical generator to the reaction solution after the completion of polymerization to effect the replacement, and a method of isolating the polymer after the completion of polymerization, again dissolving the polymer in a solvent, and then adding a radical generator, but a method of adding a radical generator to the reaction solution after the completion of polymerization to effect the replacement is preferred in view of efficiency. As for the radical generator, those described above as the radical initiator may be used. The radical generator may be the same as or different from the radical initiator used at the polymerization. The amount of the radical generator used is preferably from 0.01 to 20.0 molar equivalents, more preferably from 0.1 to 10.0 molar equivalents, based on the chain transfer agent of formula (CT). The reaction temperature is preferably a temperature in the range described above for the polymerization temperature. The method for adding the radical generator includes a method by en block addition, a method by addition in parts, and a method of forming a solution and adding dropwise the solution, but a method by addition in parts and a method by dropwise addition are preferred in view of safety.

In the positive photosensitive composition of the present invention, the amount of the resin as the component (B) blended in the entire composition is preferably from 50 to 99.99 mass %, more preferably from 60 to 99.0 mass %, based on the entire solid content.

In the present invention, one kind of the resin as the component (B) may be used or a plurality of kinds thereof may be used in combination.

### Resin not Having a Group Capable of Decomposing Under the Action of an Acid:

The positive resist composition of the present invention may contain a resin not having a group capable of decomposing under the action of an acid.

The term “not having a group capable of decomposing under the action of an acid” means that the resin exhibits no or very low decomposability for the action of an acid in the image forming process where the positive resist composition of the present invention is usually used, and is substantially free of a group contributing to the image formation utilizing the acid decomposition. Such a resin includes a resin having an alkali-soluble group, and a resin having a group capable of decomposing under the action of an alkali to increase the solubility in an alkali developer.

The resin not having a group capable of decomposing under the action of an acid is preferably a resin having at least one repeating unit derived from a (meth)acrylic acid derivative and/or an alicyclic olefin derivative.

The alkali-soluble group contained in the resin not having a group capable of decomposing under the action of an acid is preferably a carboxyl group, a phenolic hydroxyl group, an aliphatic hydroxyl group substituted by an electron-withdrawing group at the 1- or 2-position, an electron-withdrawing group-substituted amino group (e.g., sulfonamide, sulfonimide, bis-sulfonylimide), or an electron-withdrawing group-substituted methylene or methine group (for example, a methylene or methine group substituted by at least two members selected from a ketone group and an ester group).

The group capable of decomposing under the action of an alkali to increase the solubility in an alkali developer, which is contained in the resin not having a group capable of decomposing under the action of an acid, is preferably a lactone group or an acid anhydride group, more preferably a lactone group.

The resin not having a group capable of decomposing under the action of an acid may contain a functional group-containing repeating unit other than those described above. As for the other functional group-containing repeating unit, an appropriate functional group may be introduced by taking into consideration the dry etching resistance, hydrophilicity/hydrophobicity, interaction and the like. Examples of the other repeating unit include a constitutional unit having a polar functional group such as hydroxyl group, cyano group, carbonyl group and ester group, a repeating unit having a monocyclic or polycyclic hydrocarbon structure, a repeating unit having a silicon atom, a halogen atom or a fluoroalkyl group, and a repeating unit having a plurality of these functional groups.

Specific preferred examples of the resin not having a group capable of decomposing under the action of an acid are set forth below, but the present invention is not limited thereto.

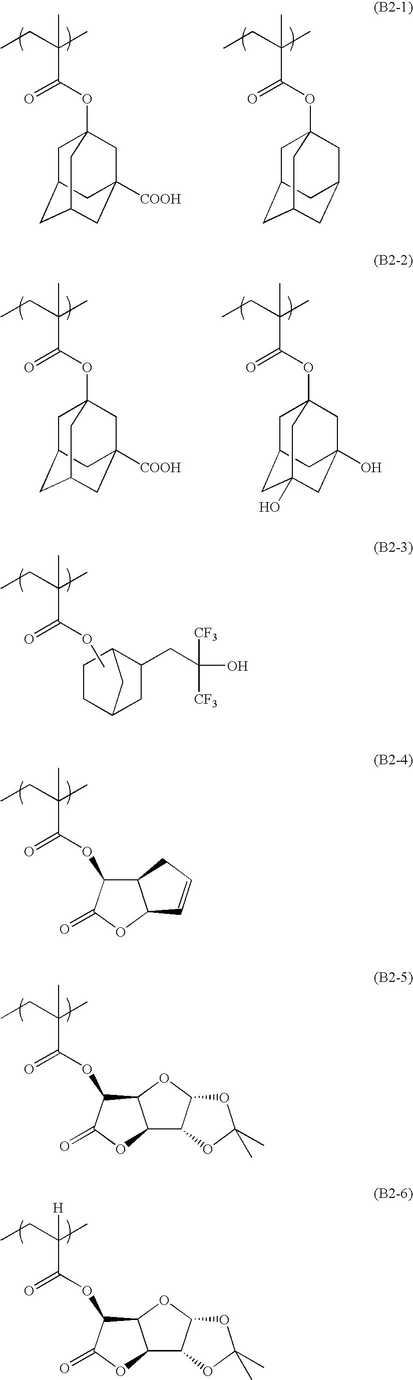

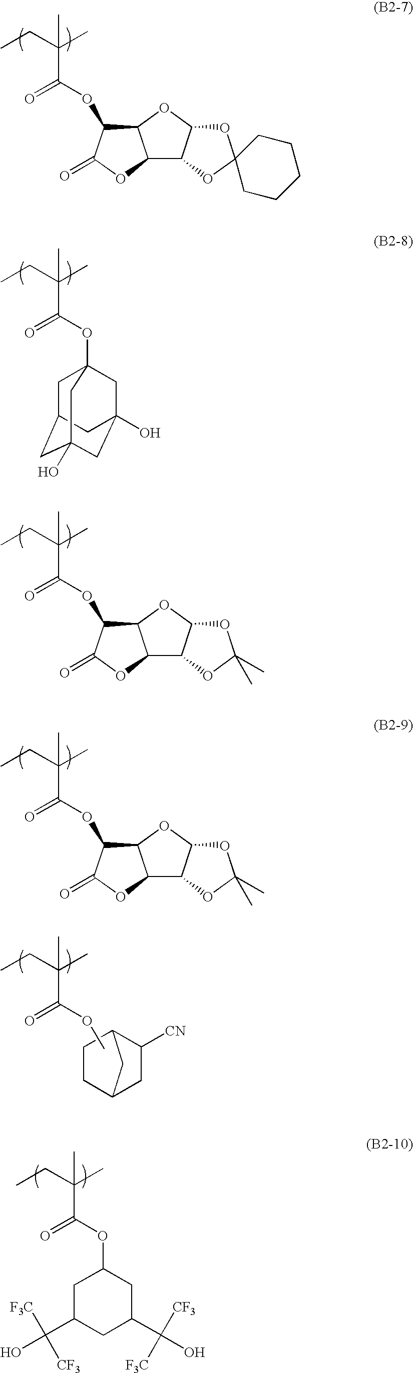

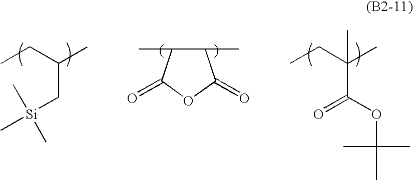

The amount added of the resin not having a group capable of decomposing under the action of an acid is from 0 to 30 mass %, preferably from 0 to 20 mass %, more preferably from 0 to 15 mass %, based on the acid-decomposable resin.

Dissolution controlling compound containing at least one member selected from an alkali-soluble group, a hydrophilic group and an acid-decomposable group and having a molecular weight of 3,000 or less:

In the positive resist composition of the present invention, a dissolution controlling compound containing at least one member selected from an alkali-soluble group, hydrophilic group and an acid-decomposable group and having a molecular weight of 3,000 or less (hereinafter sometimes referred to as a “dissolution controlling compound”) may be added.

The dissolution controlling compound is preferably a compound containing an alkali-soluble group such as carboxyl group, sulfonylimide group and hydroxyl group substituted by a fluoroalkyl group at the α-position, a compound containing a hydrophilic group such as hydroxyl group, lactone group, cyano group, amide group, pyrrolidone group and sulfonamide group, or a compound containing a group capable of decomposing under the action of an acid to release an alkali-soluble group or a hydrophilic group. The group capable of decomposing under the action of an acid to release an alkali-soluble group or a hydrophilic group is preferably a group in which a carboxyl group or a hydroxyl group is protected by an acid-decomposable group. As regards the dissolution controlling compound, for the purpose of not decreasing the transparency to light at 220 nm or less, it is preferred to use an aromatic ring-free compound or use an aromatic ring-containing compound in an added amount of 20 wt % or less based on the solid content of the composition.

The dissolution controlling compound is preferably a carboxylic acid compound having an alicyclic hydrocarbon structure, such as adamantane (di)carboxylic acid, norbornane carboxylic acid and cholic acid, a compound obtained by protecting the carboxylic acid thereof with an acid-decomposable group, a polyol such as sugars, or a compound obtained by protecting the hydroxyl group thereof with an acid-decomposable group.

The molecular weight of the dissolution controlling compound for use in the present invention is 3,000 or less, preferably from 300 to 3,000, more preferably from 500 to 2,500.

The amount of the dissolution controlling compound added is preferably from 3 to 40 mass %, more preferably from 5 to 20 mass %, based on the solid content of the positive resist composition.

Specific examples of the dissolution controlling compound are set forth below, but the present invention is not limited thereto.

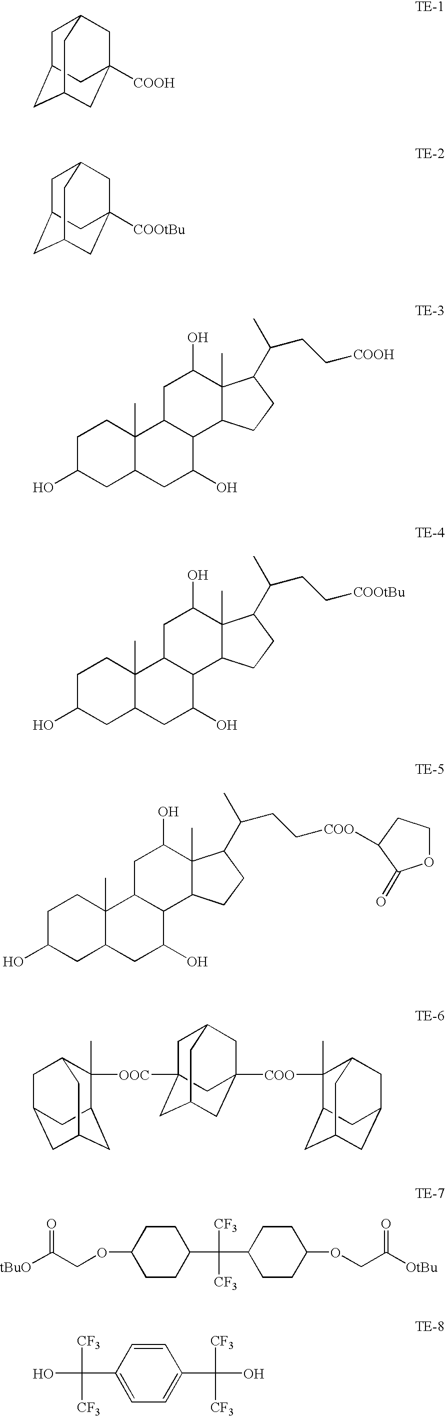

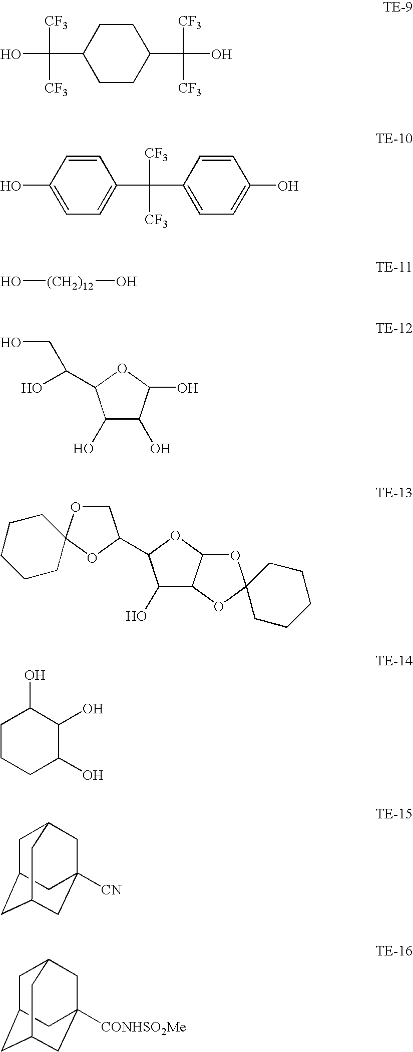

### Basic Compound:

The positive resist composition of the present invention preferably contains a basic compound so as to reduce the change in performance with aging from exposure until heating or control the diffusibility in film of the acid generated upon exposure.

The basic compound includes a nitrogen-containing basic compound and an onium salt compound. As for the structure of the nitrogen-basic compound, the compounds having a partial structure represented by any one of the following formulae (A) to (E) are preferred.

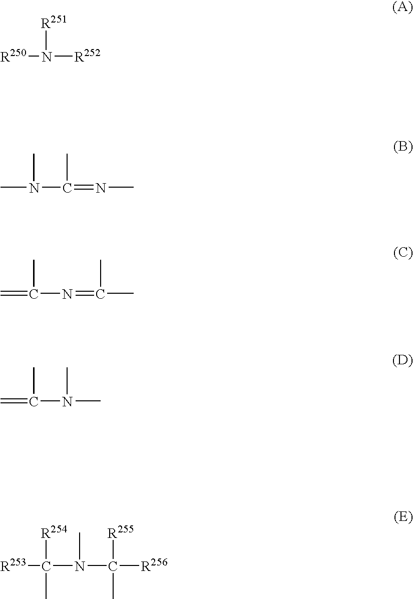

In formula (A), R²⁵⁰, R²⁵¹ and R²⁵² each independently represents a hydrogen atom, an alkyl group having a carbon number of 1 to 20, a cycloalkyl group having a carbon number of 3 to 20, or an aryl group having a carbon number of 6 to 20, and R²⁵⁰ and R²⁵¹ may combine with each other to form a ring. These groups each may have a substituent. The alkyl or cycloalkyl group having a substituent is preferably an aminoalkyl group having a carbon number of 1 to 20, an aminocycloalkyl group having a carbon number of 3 to 20, a hydroxyalkyl group having a carbon number of 1 to 20, or a hydroxycycloalkyl group having a carbon number of 3 to 20.

The alkyl chain thereof may contain an oxygen atom, a sulfur atom or a nitrogen atom.

In formula (E), R²⁵³, R²⁵⁴, R²⁵⁵ and R²⁵⁶ each independently represents an alkyl group having a carbon number of 1 to 6 or a cycloalkyl group having a carbon number of 3 to 6.

Preferred examples of the compound include guanidine, aminopyrrolidine, pyrazole, pyrazoline, piperazine, aminomorpholine, aminoalkylmorpholine and piperidine, and these compounds each may have a substituent. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, benzimidazole and 2-phenylbenzimidazole. Examples of the compound having a diazabicyclo structure include 1,4-diazabicyclo[2,2,2]octane, 1,5-diazabicyclo[4,3,0]non-5-ene and 1,8-diazabicyclo[5,4,0]undec-7-ene. Examples of the compound having an onium hydroxide structure include a triarylsulfonium hydroxide, a phenacylsulfonium hydroxide and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound where the anion moiety of the compound having an onium hydroxide structure is converted into a carboxylate, and examples thereof include acetate, adamantane-1-carboxylate and perfluoroalkyl carboxylate. Examples of the compound having a trialkylamine structure include tri(n-butyl)amine and tri(n-octyl)amine. Examples of the aniline compound include 2,6-diisopropylaniline and N,N-dimethylaniline. Examples of the alkylamine derivative having a hydroxyl group and/or an ether bond include ethanolamine, diethanolamine, triethanolamine, tris(methoxyethoxyethyl)amine and N-phenyldiethanolamine. Examples of the aniline derivative having a hydroxyl group and/or an ether bond include N,N-bis(hydroxyethyl)aniline.

The preferred basic compound further includes an amine compound having a phenoxy group, and an ammonium salt compound having a phenoxy group.

As for the amine compound, a primary, secondary or tertiary amine compound can be used, and an amine compound where at least one alkyl group is bonded to the nitrogen atom is preferred. The amine compound is more preferably a tertiary amine compound. In the amine compound, as long as at least one alkyl group (preferably having a carbon number of 1 to 20) is bonded to the nitrogen atom, a cycloalkyl group (preferably having a carbon number of 3 to 20) or an aryl group (preferably having a carbon number of 6 to 12) may be bonded to the nitrogen atom in addition to the alkyl group.

The amine compound preferably has an oxygen atom in the alkyl chain to form an oxyalkylene group. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

As for the ammonium salt compound, a primary, secondary, tertiary or quaternary ammonium salt compound can be used, and an ammonium salt compound where at least one alkyl group is bonded to the nitrogen atom is preferred. In the ammonium salt compound, as long as at least one alkyl group (preferably having a carbon number of 1 to 20) is bonded to the nitrogen atom, a cycloalkyl group (preferably having a carbon number of 3 to 20) or an aryl group (preferably having a carbon number of 6 to 12) may be bonded to the nitrogen atom in addition to the alkyl group.

The ammonium salt compound preferably has an oxygen atom in the alkyl chain to form an oxyalkylene group. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

Examples of the anion of the ammonium salt compound include a halogen atom, a sulfonate, a borate and a phosphate, with a halogen atom and a sulfonate being preferred. The halogen atom is preferably chloride, bromide or iodide, and the sulfonate is preferably an organic sulfonate having a carbon number of 1 to 20. Examples of the organic sulfonate include an alkylsulfonate having a carbon number of 1 to 20 and an arylsulfonate. The alkyl group of the alkylsulfonate may have a substituent, and examples of the substituent include fluorine, chlorine, bromine, an alkoxy group, an acyl group and an aryl group. Specific examples of the alkylsulfonate include methanesulfonate, ethanesulfonate, butanesulfonate, hexanesulfonate, octanesulfonate, benzylsulfonate, trifluoromethanesulfonate, pentafluoroethanesulfonate and nonafluorobutanesulfonate. The aryl group of the arylsulfonate includes a benzene ring, a naphthalene ring and an anthracene ring. The benzene ring, naphthalene ring and anthracene ring each may have a substituent, and the substituent is preferably a linear or branched alkyl group having a carbon number of 1 to 6, or a cycloalkyl group having a carbon number of 3 to 6. Specific examples of the linear or branched alkyl group and the cycloalkyl group include methyl, ethyl, n-propyl, isopropyl, n-butyl, i-butyl, tert-butyl, n-hexyl and cyclohexyl. Other examples of the substituent include an alkoxy group having a carbon number of 1 to 6, a halogen atom, cyano, nitro, an acyl group and an acyloxy group.

The amine compound having a phenoxy group and the ammonium salt compound having a phenoxy group are a compound where the alkyl group of an amine compound or ammonium salt compound has a phenoxy group at the terminal opposite the nitrogen atom. The phenoxy group may have a substituent. Examples of the substituent of the phenoxy group include an alkyl group, an alkoxy group, a halogen atom, a cyano group, a nitro group, a carboxyl group, a carboxylic acid ester group, a sulfonic acid ester group, an aryl group, an aralkyl group, an acyloxy group and an aryloxy group. The substitution site of the substituent may be any of 2- to 6-positions, and the number of substituents may be any in the range from 1 to 5.

The compound preferably has at least one oxyalkylene group between the phenoxy group and the nitrogen atom. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred. The amine compound having a phenoxy group can be obtained by reacting a primary or secondary amine having a phenoxy group with a haloalkyl ether under heating, adding an aqueous solution of strong base such as sodium hydroxide, potassium hydroxide and tetraalkylammonium, and performing extraction with an organic solvent such as ethyl acetate and chloroform, or by reacting a primary or secondary amine with a haloalkyl ether having a phenoxy group at the terminal under heating, adding an aqueous solution of strong base such as sodium hydroxide, potassium hydroxide and tetraalkylammonium, and performing extraction with an organic solvent such as ethyl acetate and chloroform.

One of these basic compounds may be used alone, or two or more thereof may be used in combination.

The amount of the basic compound used is usually from 0.001 to 10 mass %, preferably from 0.01 to 5 mass %, based on the solid content of the positive resist composition. The amount used is preferably 0.001 mass % or more for obtaining a sufficiently high addition effect and preferably 10 mass % or less in view of sensitivity and developability of the unexposed area.

Fluorine-Containing and/or Silicon-Containing Surfactant:

The positive resist composition of the present invention preferably further contains any one fluorine-containing and/or silicon-containing surfactant (a fluorine-containing surfactant, a silicon-containing surfactant, or a surfactant containing both a fluorine atom and a silicon atom), or two or more kinds thereof.

When the positive resist composition of the present invention contains a fluorine-containing and/or silicon-containing surfactant, in the case of using an exposure light source emitting light at 250 nm or less, particularly 220 nm or less, a resist pattern assured of good adhesion and less development defect can be obtained with good sensitivity and resolution.

Examples of the fluorine-containing and/or silicon-containing surfactant include the surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, JP-A-2002-277862 and U.S. Pat. Nos. 5,405,720, 5,360,692, 5,529,881, 5,296,330, 5,436,098, 5,576,143, 5,294,511 and 5,824,451. The following commercially available surfactants may also be directly used.

Examples of the commercially available surfactant which can be used include a fluorine-containing or silicon-containing surfactant such as EFtop EF301 and EF303 (produced by Shin-Akita Chemical Co., Ltd.), Florad FC430 and 431 (produced by Sumitomo 3M Inc.), Megafac F171, F173, F176, F189 and R08 (produced by Dainippon Ink & Chemicals, Inc.), Surflon S-382, SC101, 102, 103, 104, 105 and 106 (produced by Asahi Glass Co., Ltd.), and Troysol S-366 (produced by Troy Chemical Industries, Inc.). In addition, polysiloxane polymer KP-341 (produced by Shin-Etsu Chemical Co., Ltd.) may also be used as the silicon-containing surfactant.

Other than those known surfactants, a surfactant using a polymer having a fluoro-aliphatic group derived from a fluoro-aliphatic compound produced by a telomerization process (also called a telomer process) or an oligomerization process (also called an oligomer process) may be used. The fluoro-aliphatic compound can be synthesized by the method described in JP-A-2002-90991.

The polymer having a fluoro-aliphatic group is preferably a copolymer of fluoro-aliphatic group-containing monomer with (poly(oxyalkylene))acrylate and/or (poly(oxyalkylene))methacrylate, and the polymer may have an irregular distribution or may be a block copolymer. Examples of the poly(oxyalkylene) group include a poly(oxyethylene) group, a poly(oxypropylene) group and a poly(oxybutylene) group. This group may also be a unit having alkylenes differing in the chain length within the same chain, such as block-linked poly(oxyethylene, oxypropylene and oxyethylene) and block-linked poly(oxyethylene and oxypropylene). Furthermore, the copolymer of fluoro-aliphatic group-containing monomer with (poly(oxyalkylene))acrylate (or methacrylate) may be not only a binary copolymer but also a ternary or higher copolymer obtained by simultaneously copolymerizing two or more different fluoro-aliphatic group-containing monomers or two or more different (poly(oxyalkylene))acrylates (or methacrylates).

Examples thereof include commercially available surfactants such as Megafac F178, F-470, F-473, F-475, F-476 and F-472 (produced by Dainippon Ink & Chemicals, Inc.), and further include a copolymer of C₆F₁₃ group-containing acrylate (or methacrylate) with (poly(oxyalkylene))acrylate (or methacrylate), a copolymer of C₆F₁₃ group-containing acrylate (or methacrylate) with (poly(oxyethylene))acrylate (or methacrylate) and (poly(oxy-propylene)) acrylate (or methacrylate), a copolymer of C₈F₁₇ group-containing acrylate (or methacrylate) with (poly(oxyalkylene))acrylate (or methacrylate), and a copolymer of C₈F₁₇ group-containing acrylate (or methacrylate) with (poly(oxyethylene))acrylate (or methacrylate) and (poly(oxypropylene))acrylate (or methacrylate).

The amount of the fluorine-containing and/or silicon-containing surfactant used is preferably from 0.0001 to 2 mass %, more preferably from 0.001 to 1 mass %, based on the entire amount of the positive resist composition (excluding the solvent).

### Organic Solvent:

The positive resist composition of the present invention is used by dissolving the components described above in a predetermined organic solvent.

Examples of the organic solvent which can be used include ethylene dichloride, cyclohexanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, methyl lactate, ethyl lactate, methyl methoxypropionate, ethyl ethoxypropionate, methyl pyruvate, ethyl pyruvate, propyl pyruvate, N,N-dimethylformamide, dimethylsulfoxide, N-methylpyrrolidone and tetrahydrofuran.

In the present invention, one organic solvent may be used alone or some organic solvents may be mixed and used, but it is preferred to use a mixed solvent containing two or more kinds of solvents having different functional groups. By the use of a mixed solvent, the solubility of raw materials is increased and not only the production of particles with aging can be suppressed but also a good pattern profile can be obtained. The functional group contained in the solvent is preferably an ester group, a lactone group, a hydroxyl group, a ketone group or a carbonate group. As for the mixed solvent having different functional groups, the following mixed solvents (S1) to (S5) are preferred:

(S1) a mixed solvent obtained by mixing a hydroxyl group-containing solvent and a hydroxyl group-free solvent;

(S2) a mixed solvent obtained by mixing a solvent having an ester structure and a solvent having a ketone structure;

(S3) a mixed solvent obtained by mixing a solvent having an ester structure and a solvent having a lactone structure;

(S4) a mixed solvent obtained by mixing a solvent having an ester structure, a solvent having a lactone structure, and a hydroxyl group-containing solvent; and

(S5) a mixed solvent containing a solvent having an ester structure, a solvent having a carbonate structure, and a hydroxyl group-containing solvent.

By the use of such a mixed solvent, production of particles during storage of the resist solution can be reduced, and generation of a defect at the coating can be suppressed.

Examples of the hydroxyl group-containing solvent include ethylene glycol, ethylene glycol monomethyl ether, ethylene glycol monoethyl ether, propylene glycol, propylene glycol monomethyl ether, propylene glycol monoethyl ether and ethyl lactate. Among these, propylene glycol monomethyl ether and ethyl lactate are preferred.

Examples of the hydroxyl group-free solvent include propylene glycol monomethyl ether acetate, ethyl ethoxy propionate, 2-heptanone, γ-butyrolactone, cyclohexanone, butyl acetate, N-methylpyrrolidone, N,N-dimethylacetamide and dimethyl sulfoxide. Among these, propylene glycol monomethyl ether acetate, ethyl ethoxy propionate, 2-heptanone, γ-butyrolactone, cyclohexanone and butyl acetate are preferred, and propylene glycol monomethyl ether acetate, ethyl ethoxy propionate, 2-heptanone and cyclohexanone are more preferred.

Examples of the solvent having a ketone structure include cyclohexanone and 2-heptanone, with cyclohexanone being preferred.

Examples of the solvent having an ester structure include propylene glycol monomethyl ether acetate, ethyl ethoxy propionate and butyl acetate, with propylene glycol monomethyl ether acetate being preferred.

Examples of the solvent having a lactone structure include (-butyrolactone.

Examples of the solvent having a carbonate structure include propylene carbonate and ethylene carbonate, with propylene carbonate being preferred.

The mixing ratio (by mass) of the hydroxyl group-containing solvent to the hydroxyl group-free solvent is from 1/99 to 99/1, preferably from 10/90 to 90/10, more preferably from 20/80 to 60/40. A mixed solvent containing 50 mass % or more of a hydroxyl group-free solvent is particularly preferred in view of coating uniformity.

The mixing ratio (by mass) of the solvent having an ester structure to the solvent having a ketone structure is from 1/99 to 99/1, preferably from 10/90 to 90/10, more preferably from 40/60 to 80/20. A mixed solvent containing 50 mass % or more of a solvent having an ester structure is particularly preferred in view of coating uniformity.

The mixing ratio (by mass) of the solvent having an ester structure to the solvent having a lactone structure is from 70/30 to 99/1, preferably from 80/20 to 99/1, more preferably from 90/10 to 99/1. A mixed solvent containing 70 mass % or more of a solvent having an ester structure is particularly preferable in view of aging stability.

In the case of mixing a solvent having an ester structure, a solvent having a lactone structure and a hydroxyl group-containing solvent, the mixed solvent preferably contains from 30 to 80 mass % of a solvent having an ester structure, from 1 to 20 mass % of a solvent having a lactone structure, and from 10 to 60 mass % of a hydroxyl group-containing solvent.

In the case of mixing a solvent having an ester structure, a solvent having a carbonate structure and a hydroxyl group-containing solvent, the mixed solvent preferably contains from 30 to 80 mass % of a solvent having an ester structure, from 1 to 20 mass % of a solvent having a carbonate structure, and from 10 to 60 mass % of a hydroxyl group-containing solvent.

A preferred embodiment of the solvent is a solvent containing an alkylene glycol monoalkyl ether carboxylate (preferably propylene glycol monomethyl ether acetate). A mixed solvent of an alkylene glycol monoalkyl ether carboxylate with another solvent is more preferred, where the another solvent is at least one solvent having a functional group selected from a hydroxyl group, a ketone group, a lactone group, an ester group, an ether group and a carbonate group, or a plurality of these functional groups in combination. In particular, the mixed solvent is preferably a mixed solvent containing at least one member selected from ethyl lactate, γ-butyrolactone, propylene glycol monomethyl ether, butyl acetate and cyclohexanone, and propylene glycol monomethyl ether acetate.

By selecting an optimal solvent, the performance in terms of development defect can be improved.

### <Other Additives>

If desired, the positive resist composition of the present invention may further contain, for example, a dye, a plasticizer, a surfactant other than the fluorine-containing and/or silicon-containing surfactant above, a photosensitizer, and a compound capable of accelerating the dissolution in a developer.

The compound capable of accelerating the dissolution in a developer, which can be used in the present invention, is a low molecular compound containing two or more phenolic OH groups or one or more carboxy groups and having a molecular weight of 1,000 or less. In the case of containing a carboxyl group, an alicyclic or aliphatic compound is preferred.

The amount of the dissolution accelerating compound added is preferably from 2 to 50 mass %, more preferably from 5 to 30 mass %, based on the polymer compound. The amount added is preferably 50 mass % or less from the standpoint of suppressing the development residue or preventing the deformation of pattern at the development.

The phenol compound having a molecular weight of 1,000 or less can be easily synthesized by one skilled in the art with reference to the method described, for example, in JP-A-4-122938, JP-A-2-28531, U.S. Pat. No. 4,916,210 and European Patent 219294.

Specific examples of the alicyclic or aliphatic compound having a carboxy group include, but are not limited to, a carboxylic acid derivative having a steroid structure, such as cholic acid, deoxycholic acid and lithocholic acid, an adamantane carboxylic acid derivative, an adamantane dicarboxylic acid, a cyclohexanecarboxylic acid and a cyclohexanedicarboxylic acid.

In the present invention, a surfactant other than the fluorine-containing and/or silicon-containing surfactant above may also be added. Specific examples thereof include a nonionic surfactant such as polyoxyethylene alkyl ethers, polyoxyethylene alkylallyl ethers, polyoxyethylenepolyoxypropylene block copolymers, sorbitan aliphatic esters and polyoxyethylene sorbitan aliphatic esters.

One of these surfactants may be added alone, or several members thereof may be added in combination.

### (Pattern Forming Method)

The positive resist composition of the present invention is used by dissolving the above-described components in a predetermined organic solvent, preferably in the mixed solvent above, filtering the solution, and coating it on a predetermined support as follows. The filter used for filtration is preferably a filter made of polytetrafluoroethylene, polyethylene or nylon and having a pore size of 0.1 micron or less, more preferably 0.05 microns or less, still more preferably 0.03 microns or less.

For example, the positive resist composition is coated on such a substrate (e.g., silicon/silicon dioxide-coated substrate) as used in the production of a precision integrated circuit device, by an appropriate coating method such as spinner or coater, and dried to form a resist film.

The resist film formed is irradiated with an actinic ray or radiation through a predetermined mask and preferably after baking (heating), subjected to development and rinsing, whereby a good pattern can be obtained.

At the irradiation with an actinic ray or radiation, the exposure may be performed by filling a liquid (immersion medium) having a refractive index higher than that of air between the resist film and the lens (immersion exposure). By this exposure, the resolution can be enhanced. The immersion medium used may be any liquid as long as it has a refractive index higher than that of air, but pure water is preferred. Also, an overcoat layer may be further provided on the resist film so as to prevent the immersion medium from coming into direct contact with the resist film at the immersion exposure. By virtue of this overcoat layer, dissolving out of the composition from the resist film into the immersion medium can be suppressed and the development defect can be reduced.

Before forming the resist film, an antireflection film may be previously provided by coating on the substrate.

The antireflection film used may be either an inorganic film type such as titanium, titanium dioxide, titanium nitride, chromium oxide, carbon and amorphous silicon, or an organic film type comprising a light absorbent and a polymer material. Also, the organic antireflection film may be a commercially available organic antireflection film such as DUV30 Series and DUV-40 Series produced by Brewer Science, Inc., and AR-2, AR-3 and AR-5 produced by Shipley Co., Ltd.

Examples of the actinic ray or radiation include infrared light, visible light, ultraviolet light, far ultraviolet light, X-ray and electron beam, but the radiation is preferably far ultraviolet light at a wavelength of 250 nm or less, more preferably 220 nm or less. Specific examples thereof include KrF excimer laser light (248 nm), ArF excimer laser light (193 nm), F₂ excimer laser light (157 nm), X-ray and electron beam, and ArF excimer laser light, F₂ excimer laser light, EUV (13 nm) and electron beam are preferred.

In the development step, an alkali developer is used as follows. The alkali developer for the resist composition is an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine.

Furthermore, this alkali developer may be used after adding thereto alcohols and a surfactant each in an appropriate amount.

The alkali concentration of the alkali developer is usually from 0.1 to 20 mass %.

The pH of the alkali developer is usually from 10.0 to 15.0.

The positive resist composition of the present invention may be applied to a multilayer resist process (particularly, a three-layer resist process). The multilayer resist process comprises the following steps:

(a) forming a lower resist layer comprising an organic material on a substrate to be processed,

(b) sequentially stacking, on the lower resist layer, an intermediate layer and an upper resist layer comprising an organic material capable of crosslinking or decomposing upon irradiation with radiation, and

(c) forming a predetermined pattern on the upper resist layer and then sequentially etching the intermediate layer, the lower layer and the substrate.

In general, an organopolysiloxane (silicone resin) or SiO₂ coating solution (SOG) is used for the intermediate layer. As for the lower layer resist, an appropriate organic polymer film is used, but various known photoresists may be used. Examples thereof include various Series such as FH Series and FHi Series produced by Fujifilm Arch Co., Ltd. and PFI Series produced by Sumitomo Chemical Co., Ltd.

The film thickness of the lower resist layer is preferably from 0.1 to 4.0 μm, more preferably from 0.2 to 2.0 μm, still more preferably from 0.25 to 1.5 μm. The film thickness is preferably 0.1 μm or more in view of antireflection or dry etching resistance and preferably 4.0 μm or less in the light of aspect ratio or pattern collapse of the fine pattern formed.

### Example 1

The present invention is described in greater detail below by referring to Examples, but the present invention should not be construed as being limited thereto.

### Synthesis Example 1

### Synthesis of Resin (RA-1-1)

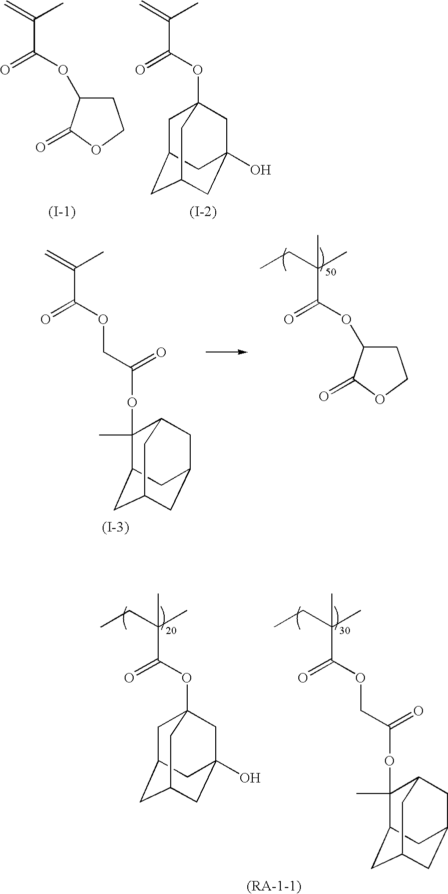

Under a nitrogen stream, 0.77 g (2.50 mmol) of Chain Transfer Agent (II-1) and 5.9 g of cyclohexanone were charged into a three-neck flask and heated at 80° C. Thereto, a solution prepared by dissolving 10.9 g (64.0 mmol) of Monomer (I-1), 6.0 g (25.6 mmol) of Monomer (I-2), 11.2 g (38.4 mmol) of Monomer (I-3) and 0.41 g (2.50 mmol) of polymerization initiator V-60 (azobisisobutyronitrile, produced by Wako Pure Chemical Industries, Ltd.) in 106 g of cyclohexanone was added dropwise over 6 hours. After the completion of dropwise addition, the reaction was further allowed to proceed at 80° C. for 2 hours. To this solution, a solution prepared by dissolving 3.36 g (10.2 mmol) of polymerization initiator V-60 (produced by Wako Pure Chemical Industries, Ltd.) in 20 mL of cyclohexanone was added dropwise at 80° C. over 4 hours, and the system was further heated for 2 hours. The reaction solution was left standing to cool and then added dropwise to a mixed solution of 700-ml hexane/300-ml ethyl acetate over 20 minutes, and the precipitated powder was collected by filtration and dried to obtain 21.4 g of Acid-Decomposable Resin (RA-1-1). The weight average molecular weight of the resin obtained was 6,300 in terms of standard polystyrene, and the dispersity (Mw/Mn) was 1.17.

### Synthesis Example 2

### Synthesis of Resin (RA-1-2)

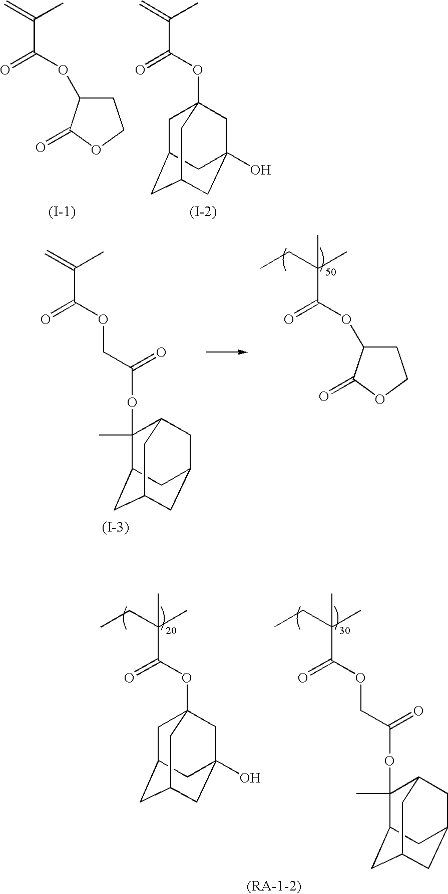

Under a nitrogen stream, 5.9 g of cyclohexanone was charged into a three-neck flask and heated at 80° C. Thereto, a solution prepared by dissolving 10.9 g (64.0 mmol) of Monomer (I-1), 6.0 g (25.6 mmol) of Monomer (I-2), 11.2 g (38.4 mmol) of Monomer (I-3) and 2.10 g (12.8 mmol) of polymerization initiator V-60 (azobisisobutyronitrile, produced by Wako Pure Chemical Industries, Ltd.) in 106 g of cyclohexanone was added dropwise over 6 hours. After the completion of dropwise addition, the system was further heated at 80° C. for 2 hours. After the completion of polymerization, 450 mL of an aqueous methanol solution (volume ratio of methanol:water=9:1) at 20° C. was added dropwise, and the precipitated solid was collected by decantation. This solid was vacuum-dried at 40° C. to obtain 15.2 g of Resin RA-1-2.

### Synthesis Examples 3 to 13, 16, 17 and 18

### Synthesis of Resins (RA-2) to (RA-15)

Resins (RA-2) to (RA-15) were synthesized in the same manner as in Synthesis Example 1 according to the conditions shown in Table 1.

### Synthesis Example 14

### Synthesis of Resin (RA-1′)

Under a nitrogen stream, 8.8 g of cyclohexanone was charged into a three-neck flask and heated at 80° C. Thereto, a solution prepared by dissolving 8.5 g (50.0 mmol) of Monomer (I-1), 4.7 g (20.0 mmol) of Monomer (I-2), 8.8 g (30.0 mmol) of Monomer (I-3), and polymerization initiator V-60 (produced by Wako Pure Chemical Industries, Ltd.) in an amount of 13 mol % based on the monomers, in 79 g of cyclohexanone was added dropwise over 6 hours. After the completion of dropwise addition, the reaction was further allowed to proceed at 80° C. for 2 hours. The reaction solution was left standing to cool and then added dropwise to a mixed solution of 900-ml methanol/100-ml water over 20 minutes, and the precipitated powder was collected by filtration and dried to obtain 18 g of Resin (RA-1′). The weight average molecular weight of the resin obtained was 6,200 in terms of standard polystyrene, and the dispersity (Mw/Mn) was 1.63.

### Synthesis Example 15

### Synthesis of Resin (RA-2′)

Resin (RA-2′) was synthesized in the same manner as in Synthesis Example 1 according to the conditions shown in Table 1.

### Synthesis Example 19

### Synthesis of Resin (RA-16): Resin not Having a Spacer

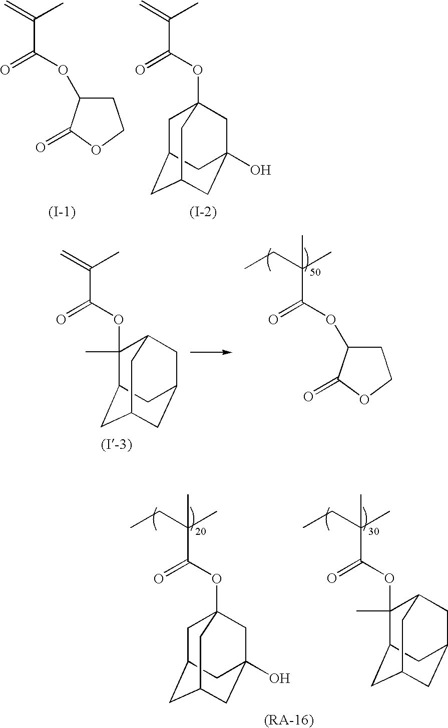

Under a nitrogen stream, 0.77 g (2.50 mmol) of Chain Transfer Agent (II-1) and 5.9 g of cyclohexanone were charged into a three-neck flask and heated at 80° C. Thereto, a solution prepared by dissolving 10.9 g (64.0 mmol) of Monomer (I-1), 6.0 g (25.6 mmol) of Monomer (I-2), 9.0 g (38.4 mmol) of Monomer (I'-3) and 0.41 g (2.50 mmol) of polymerization initiator V-60 (azobisisobutyronitrile, produced by Wako Pure Chemical Industries, Ltd.) in 106 g of cyclohexanone was added dropwise over 6 hours. After the completion of dropwise addition, the reaction was further allowed to proceed at 80° C. for 2 hours. To this solution, a solution prepared by dissolving 3.36 g (10.2 mmol) of polymerization initiator V-60 (produced by Wako Pure Chemical Industries, Ltd.) in 20 mL of cyclohexanone was added dropwise at 80° C. over 4 hours, and the system was further heated for 2 hours. The reaction solution was left standing to cool and then added dropwise to a mixed solution of 700-ml hexane/300-ml ethyl acetate over 20 minutes, and the precipitated powder was collected by filtration and dried to obtain 21.4 g of Acid-Decomposable Resin (RA-16). The weight average molecular weight of the resin obtained was 7,300 in terms of standard polystyrene, and the dispersity (Mw/Mn) was 1.24.

Structures of resins used in Examples and Comparative Examples are shown below.

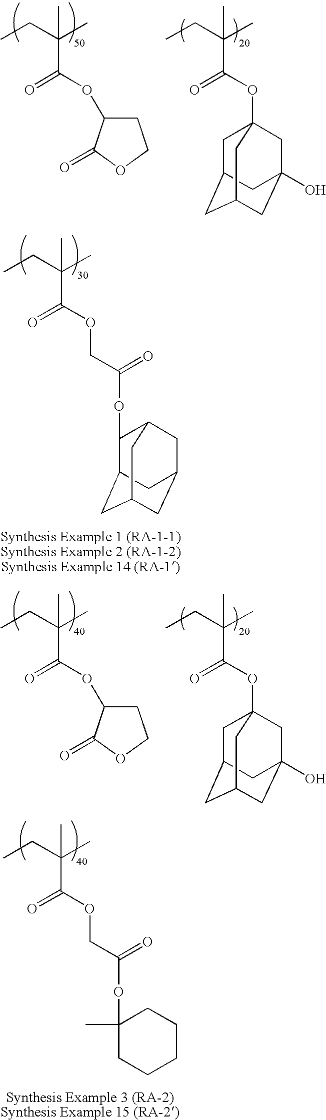

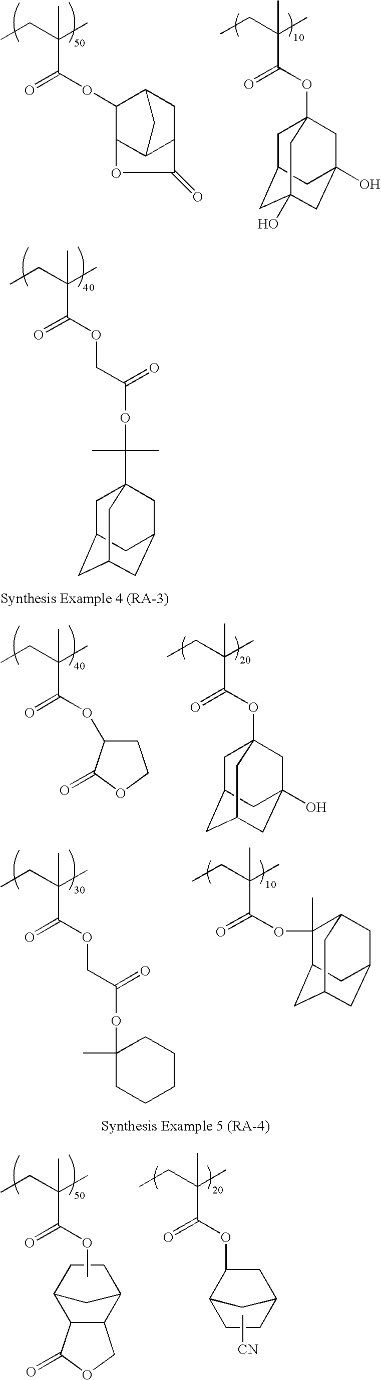

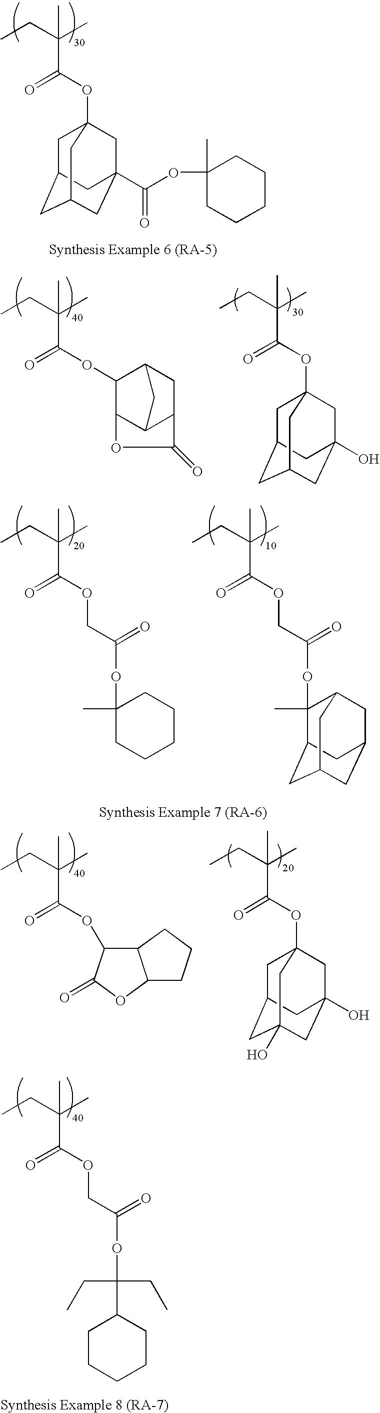

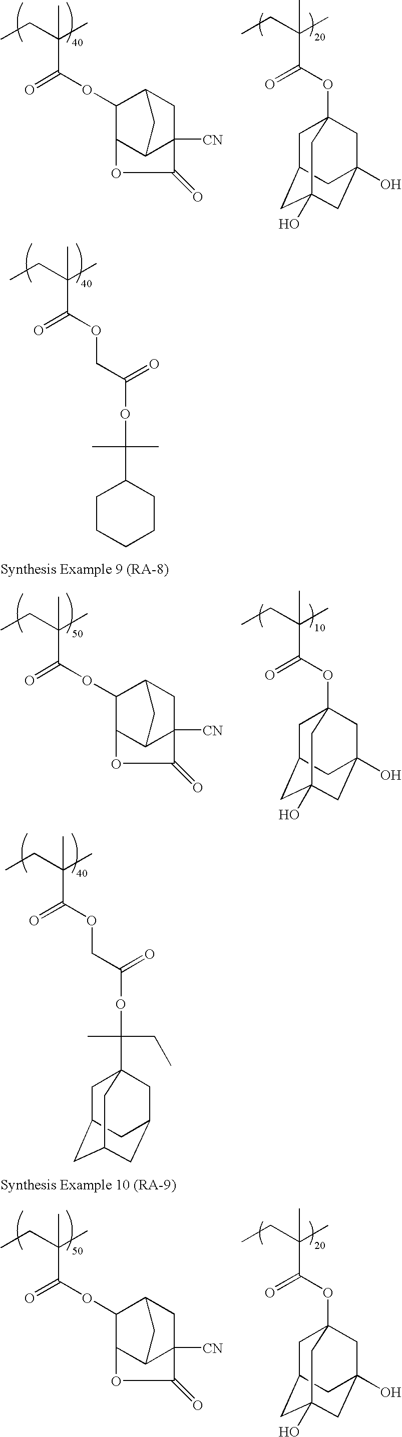

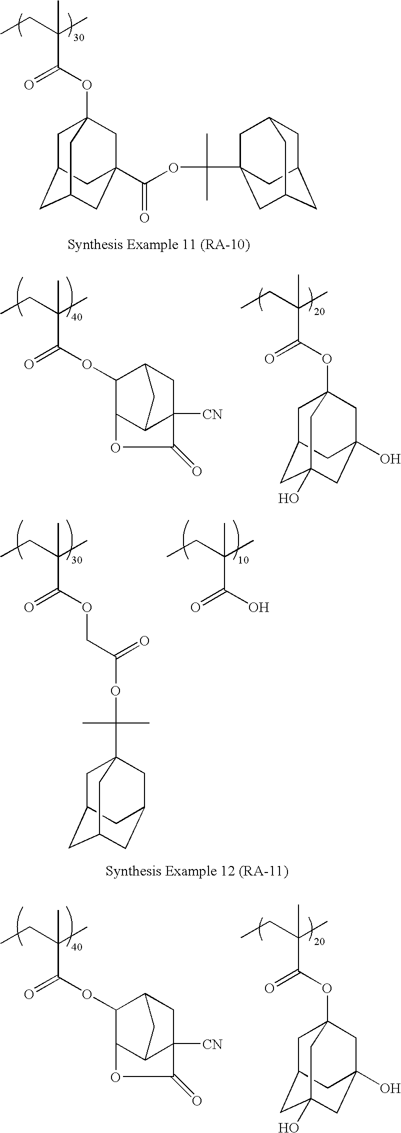

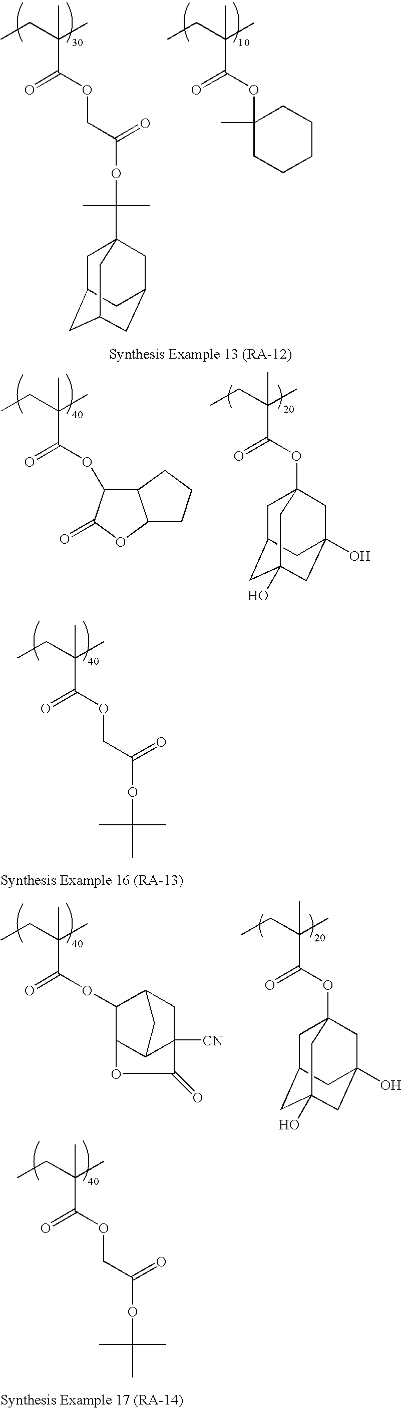

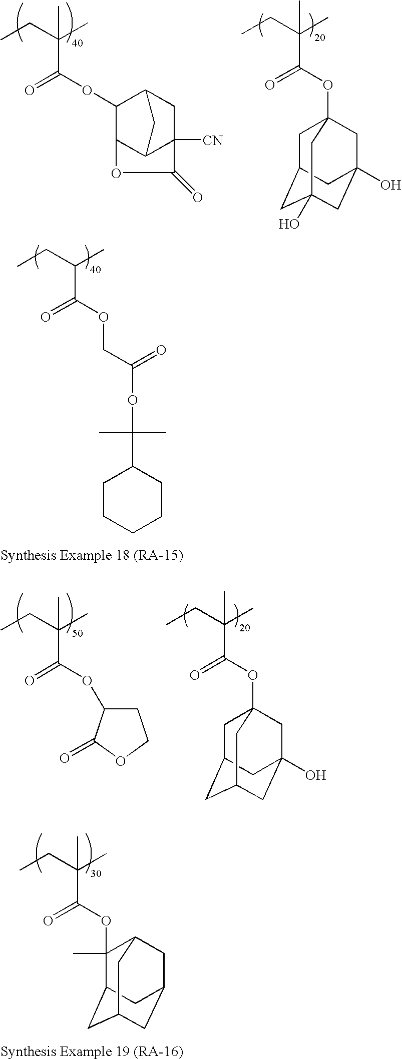

With respect to the obtained acid-decomposable resins, the initiator and chain transfer agent used, the weight average molecular weight, the dispersity (Mw/Mn) and the transmittance are shown in Table 1 below. As for the transmittance, a resin solution in propylene glycol monoacetate:propylene glycol=6:4 (resin content: 10 wt %) was spin-coated on a quartz glass substrate and prebaked at 120° C. to form a resist film having a film pressure of 160 nm, and the transmittance was calculated from the absorbance at a wavelength of 193 nm of the film.

TABLE 1

| | | | Chain Transfer | Weight Average | | Transmittance |
|---|---|---|---|---|---|---|
| | Resin | Initiator (mol %) | Agent (mol %) | Molecular Weight | Dispersity | (%) |
| Synthesis Example 1 | RA-1-1 | V-60 (2.5) | (II-1) (2.5) | 6300 | 1.17 | 89 |
| Synthesis Example 2 | RA-1-2 | V-60 (10.0) | — | 7200 | 1.41 | 92 |
| Synthesis Example 3 | RA-2 | V-601 (1.5) | (II-1) (1.5) | 7500 | 1.18 | 89 |
| Synthesis Example 4 | RA-3 | V-60 (2) | (II-1) (2) | 6500 | 1.17 | 90 |
| Synthesis Example 5 | RA-4 | V-601 (1.5) | (II-1) (1.5) | 8200 | 1.19 | 89 |
| Synthesis Example 6 | RA-5 | V-40 (2.5) | (II-1) (2.5) | 5500 | 1.17 | 89 |
| Synthesis Example 7 | RA-6 | V-60 (1.5) | (II-2) (1.5) | 8900 | 1.36 | 89 |
| Synthesis Example 8 | RA-7 | V-60 (2) | (II-9) (4) | 7500 | 1.16 | 90 |
| Synthesis Example 9 | RA-8 | V-60 (2) | (II-9) (4) | 8200 | 1.15 | 91 |
| Synthesis Example 10 | RA-9 | V-65 (1.5) | (II-1) (1.5) | 9900 | 1.16 | 90 |
| Synthesis Example 11 | RA-10 | V-60 (1.5) | (II-5) (1.5) | 8500 | 1.17 | 89 |
| Synthesis Example 12 | RA-11 | V-60 (2) | (II-5) (2) | 7400 | 1.17 | 89 |
| Synthesis Example 13 | RA-12 | V-40 (1.5) | (II-1) (3) | 9100 | 1.18 | 90 |
| Synthesis Example 14 | RA-1′ | V-60 (13) | — | 6200 | 1.63 | 90 |
| Synthesis Example 15 | RA-2′ | V-60 (13) | — | 6200 | 1.75 | 89 |
| Synthesis Example 16 | RA-13 | V-60 (2.5) | (II-1) (2.5) | 7800 | 1.21 | 90 |
| Synthesis Example 17 | RA-14 | V-60 (2.5) | (II-1) (2.5) | 8200 | 1.23 | 90 |
| Synthesis Example 18 | RA-15 | V-60 (2.5) | (II-1) (2.5) | 8200 | 1.23 | 90 |
| Synthesis Example 19 | RA-16 | V-60 (2.5) | (II-1) (2.5) | 7300 | 1.24 | 90 |

### Examples 1 to 13 and Comparative Examples 1 and 2

### Evaluation 1 of Resist

### <Preparation of Resist>

The components shown in Table 2 below were dissolved in a solvent to prepare a solution having a solid material concentration of 8 mass %, and this solution was filtered through a polyethylene filter having a pore size of 0.03 micron to prepare a positive resist solution. The positive resist solutions prepared were evaluated by the following methods, and the results are shown in Table 3.

### <Pattern Forming Method>

On a silicon substrate treated with hexamethyldisilazane, antireflection film DUV-42 produced by Brewer Science, Inc. was uniformly coated by a spin coater to a thickness of 600 Å. The coated film was then dried at 100° C. for 90 seconds on a hot plate and further dried under heating at 190° C. for 240 seconds. Thereafter, the positive resist solutions each was coated thereon by a spin coater and dried at 120° C. for 60 seconds to form a 160-nm resist film.

This resist film was exposed using an ArF excimer laser stepper (manufactured by ASML, NA=0.75, dipole) through a mask and immediately after the exposure, heated at 120° C. for 60 seconds on a hot plate. Thereafter, the resist film was developed with an aqueous 2.38 mass % tetramethylammonium hydroxide solution at 23° C. for 60 seconds, rinsed with pure water for 30 seconds and then dried to obtain a line pattern.

### Evaluation 2 of Resist

### <Preparation of Resist>

The components shown in Table 2 below and surface-hydrophobed resin Polymer-A were dissolved such that the coated film could give a receding contact angle of 70 to 75° for pure water, whereby a solution having a solid material concentration of 8 mass % was prepared. This solution was filtered through a 0.03-μm polyethylene filter to prepare a positive resist solution. The prepared positive solutions were evaluated by the following methods, and the results are shown in Table 2.

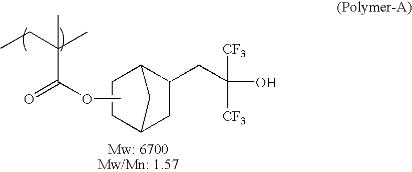

### <Pattern Forming Method>

A line pattern was obtained in the same manner as in Evaluation 1 of Resist except for performing immersion exposure by using an ArF excimer laser immersion scanner (NA=0.85) and using ultrapure water as the immersion liquid.

### <Sensitivity>

The exposure dose for reproducing a 85-nm line-and-space (1/1) mask pattern was taken as an optimal exposure dose (Eopt). As this value is smaller, the sensitivity is higher.

### <Exposure Latitude (EL)>

Assuming that the exposure dose for reproducing a line-and-space mask pattern with a line width of 85 nm is an optimal exposure dose, the exposure dose width allowing for a pattern size of 85 nm±10% when varying the exposure dose was determined, and this value was divided by the optimal exposure amount and expressed in percentage. As the value is larger, the fluctuation of performance due to change in the exposure dose is smaller and the exposure latitude (EL) is better.

TABLE 2

| | | | | | | Evaluation 1 | | Evaluation2 | |
|---|---|---|---|---|---|---|---|---|---|
| | Resin | | Basic Compound | | Solvent | Sensitivity | | Sensitivity | |
| | (10 g) | Acid Generator (g) | (g) | Surfactant (g) | (mass ratio) | (mJ/cm²) | EL (%) | (mJ/cm²) | EL (%) |
| Example 1 | RA-1-1 | z1/z2 (0.1/0.3) | DIA (0.03) | W-1 (0.01) | S1/S5 (63/40) | 32.1 | 15.2 | 32.4 | 15.4 |
| Example 2 | RA-1-2 | z1/z2 (0.1/0.3) | DIA (0.03) | W-1 (0.01) | S1/S5 (60/40) | 32.5 | 13.9 | 32.4 | 14.2 |
| Example 3 | RA-2 | z5 (0.4) | PEA (0.05) | W-1 (0.01) | S1/S6 (60/40) | 32.5 | 15.5 | 33.2 | 15.5 |
| Example 4 | RA-3 | z4/z63 (0.1/0.2) | TEA (0.02) | W-2 (0.01) | S1/S2/S5 (50/10/40) | 32.4 | 15.6 | 32.0 | 15.7 |
| Example 5 | RA-4 | z23/z5 (0.3/0.1) | TPSA (0.03) | W-1 (0.01) | S1/S4/S6 (80/5/15) | 30.1 | 15.2 | 29.9 | 15.3 |
| Example 6 | RA-5 | z51 (0.2) | PEA (0.05) | W-4 (0.01) | S1/S5 (60/40 | 32.5 | 15.7 | 32.0 | 15.8 |
| Example 7 | RA-6 | z1/z23 (0.1/0.3) | PBI (0.05) | W-3 (0.01) | S1/S6 (60/40) | 33.2 | 14.3 | 32.1 | 14.5 |
| Example 8 | RA-7 | z62 (0.2) | TEA (0.02) | W-3 (0.01) | S1/S3/S6 (80/5/15) | 33.1 | 15.8 | 31.6 | 15.9 |
| Example 9 | RA-8 | z4/z66 (0.1/0.3) | PEA (0.05) | W-1 (0.01) | S1/S5 (60/40) | 30.1 | 15.9 | 31.1 | 16.0 |
| Example 10 | RA-9 | z51/z55 (0.2/0.1) | TEA (0.02) | W-2 (0.01) | S1/S4/S6 (80/5/15) | 29.8 | 15.5 | 30.5 | 16.1 |
| Example 11 | RA-10 | z64 (0.3) | DBA (0.03) | W-1 (0.01) | S1/S5/S7 (50/40/10) | 30.5 | 15.6 | 30.4 | 15.7 |
| Example 12 | RA-11 | z67 (0.5) | PEA (0.05) | W-2 (0.01) | S1/S4/S6 (80/5/15) | 32.4 | 15.9 | 31.2 | 15.9 |
| Example 13 | RA-12 | z23 (0.4) | TMEA (0.03) | W-1 (0.01) | S1/S4/S6 (80/5/15) | 32.1 | 15.6 | 32.5 | 15.9 |
| Example 14 | RA-13 | z1/z2 (0.1/0.3) | DIA (0.03) | W-1 (0.01) | S1/S5 (60/40) | 35.1 | 12.2 | 34.4 | 12.4 |
| Example 15 | RA-14 | z1/z2 (0.1/0.3) | DIA (0.03) | W-1 (0.01) | S1/S5 (60/40) | 36.1 | 11.9 | 33.9 | 12.0 |
| Example 16 | RA-15 | z1/z2 (0.1/0.3) | DIA (0.03) | W-1 (0.01) | S1/S5 (60/40) | 33.1 | 15.6 | 32.1 | 15.9 |
| Comparative | RA-2′ | z1/z2 (0.1/0.3) | DIA (0.03) | W-1 (0.01) | S1/S5 (60/40) | 36.4 | 10.1 | 36.2 | 9.8 |
| Example 1 | | | | | | | | | |
| Comparative | RA-1′ | z1/z2 (0.1/0.3) | DIA (0.03) | W-1 (0.01) | S1/S5 (60/40) | 34.8 | 10.2 | 34.0 | 10.5 |
| Example 2 | | | | | | | | | |
| Comparative | RA-16 | z1/z2 (0.1/0.3) | DIA (0.03) | W-1 (0.01) | S1/S5 (60/40) | 42.1 | 12.1 | 42.4 | 12.4 |
| Example 3 | | | | | | | | | |

Abbreviation in Table 2 indicate the followings.
[Photoacid Generator]

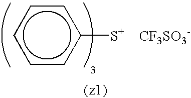

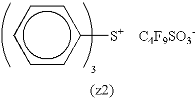

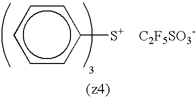

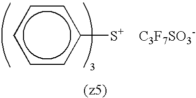

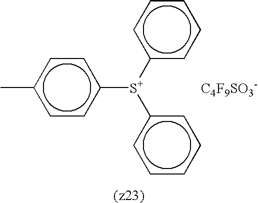

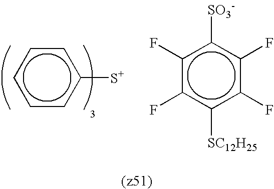

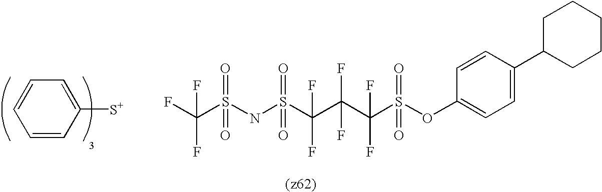

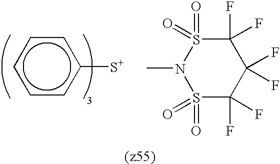

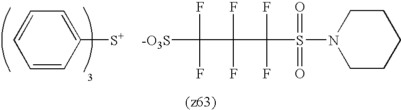

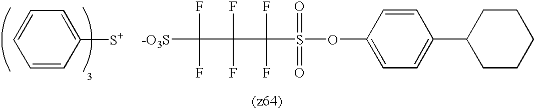

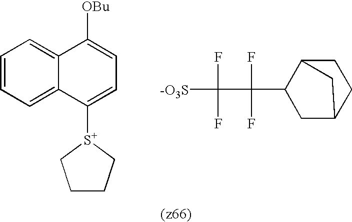

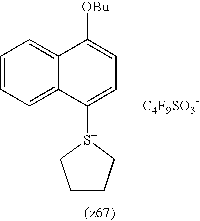

[Basic Compound]
TPSA: triphenylsulfonium acetate
DIA: 2,6-diisopropylaniline
TEA: triethanolamine
DBA: N,N-dibutylaniline
PBI: 2-phenylbenzimidazole
TMEA: tris(methoxyethoxyethyl)amine
PEA: N-phenyldiethanolamine
[Surfactant]
W-1: Megafac F176 (produced by Dainippon Ink & Chemicals, Inc.) (fluorine-containing)
W-2: Megafac R08 (produced by Dainippon Ink & Chemicals, Inc.) (fluorine- and silicon-containing)
W-3: Polysiloxane Polymer KP-341 (produced by Shin-Etsu Chemical Co., Ltd.) (silicon-containing)
W-4: Troysol S-366 (produced by Troy Chemical)
[Solvent]
S1: propylene glycol methyl ether acetate
S2: 2-heptanone
S3: cyclohexanone
S4: γ-butyrolactone
S5: propylene glycol methyl ether
S6: ethyl lactate
S7: propylene carbonate

It is apparent that the positive photosensitive composition of the present invention exhibits good image forming performance also in the exposure through immersion liquid.

### INDUSTRIAL APPLICABILITY

By virtue of using the polymer of the present invention, a positive resist composition improved in the exposure latitude at the formation of a fine pattern of 100 nm or less and assured of good sensitivity, a pattern forming method using the composition, and a production process of the polymer can be provided.

The entire disclosure of each and every foreign patent application from which the benefit of foreign priority has been claimed in the present application is incorporated herein by reference, as if fully set forth.

1. A positive resist composition comprising:
(A) a compound that generates an acid upon irradiation with an actinic ray or radiation; and
(B) a resin that has an acid-decomposable repeating unit represented by formula (I′), has a dispersity of 1.5 or less and increases its solubility in an alkali developer by action of an acid, 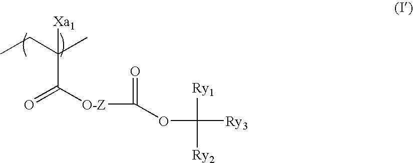
wherein Xa₁ represents a hydrogen atom, an alkyl group, a cyano group or a halogen atom;
Ry₁ to Ry₃ each independently represents an alkyl group or a cycloalkyl group, and at least two members out of Ry₁ to Ry₃ may combine to form a ring structure; and
Z represents a divalent linking group.

2. The positive resist composition as claimed in claim 1,
wherein the resin (B) is a resin produced by living radical polymerization.

3. The positive resist composition as claimed in claim 1,
wherein the resin (B) is a resin polymerized in the presence of a chain transfer agent represented by formula (CT): 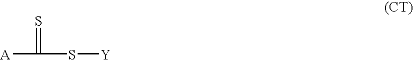
wherein A represents an alkyl group, a cycloalkyl group, an alkoxy group, an alkylthio group, an arylthio group, a heterocyclic thio group, an aryl group or a heterocyclic group; and
Y represents a group capable of releasing a radical.

4. The positive resist composition as claimed in claim 1, further comprising a basic compound.

5. A pattern forming method comprising:
forming a film with the positive resist composition claimed in claim 1; and exposing and developing the film.
